(19) United States
(12) Patent Application Publication
(10) Pub. No.: US 2009/0140251 A1
(43) Pub. Date: Jun. 4, 2009

(54) THIN FILM TRANSISTOR, DISPLAY DEVICE INCLUDING THIN FILM TRANSISTOR, AND METHOD FOR MANUFACTURING THE SAME

(75) Inventor: Shunpei YAMAZAKI, Tokyo (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/325,620

(22) Filed: Dec. 1, 2008

(30) Foreign Application Priority Data
Dec. 3, 2007 (JP) 2007-312797

(51) Int. Cl. H01L 33/00; H01L 21/02; H01L 21/3205

(52) U.S. Cl. 257/57; 257/59; 438/22; 438/585; 257/E21.002; 257/E21.214; 257/E33.002; 257/E33.055

(57) ABSTRACT

A thin film transistor having excellent electric characteristics, a display device including the thin film transistor, and a manufacturing method thereof are provided. In a thin film transistor in which a microcrystalline germanium film, a gate insulating film in contact with one surface of the microcrystalline germanium film, and a gate electrode overlap with one another and a display device including the thin film transistor, a buffer layer is formed over the other surface of the microcrystalline germanium film. By using a microcrystalline germanium film for a channel formation region, a thin film transistor with high field-effect mobility and high on-current can be manufactured, and by providing a buffer layer between the microcrystalline germanium film functioning as a channel formation region and a source and drain regions, a thin film transistor with low off-current can be manufactured, that is, a thin film transistor with excellent electric characteristics can be manufactured.

### BACKGROUND OF THE INVENTION

1. Field of the Invention

The present invention relates to a thin film transistor, a display device including the thin film transistor at least in a pixel portion, and a method for manufacturing the thin film transistor and the display device.

2. Description of the Related Art

In recent years, technology for forming thin film transistors using a thin semiconductor film (with a thickness of several tens of nanometers to several hundreds nanometers, approximately) formed over a substrate having an insulating surface has been attracting attention. Thin film transistors are applied to a wide range of electronic devices such as ICs or electro-optical devices, and prompt development of thin film transistors that are to be used as switching elements in image display devices, in particular, is being pushed.

As a switching element in an image display device, a thin film transistor including an amorphous semiconductor film, a thin film transistor including a polycrystalline semiconductor film which includes crystal grains with a diameter of 100 nm or more, or the like is used. As a method for forming a polycrystalline semiconductor film, a technique is known in which a pulsed excimer laser beam is processed into a linear shape with an optical system, and an amorphous silicon film is scanned and irradiated with the linear beam, thereby being crystallized.

As a switching element in an image display device, further, a thin film transistor including a microcrystalline silicon film or a microcrystalline silicon film including germanium is used (see Reference 1: Japanese Published Patent Application No. H4-242724 and Reference 2: Japanese Published Patent Application No. 2005-49832).

### SUMMARY OF THE INVENTION

A thin film transistor including a polycrystalline semiconductor film has advantages that the field-effect mobility thereof is two or more orders of magnitude higher than that of a thin film transistor including an amorphous semiconductor film, and that a pixel portion and a peripheral driver circuit of a semiconductor display device can be formed over one substrate. However, the thin film transistor including a polycrystalline semiconductor film requires a more complicated process than the thin film transistor including an amorphous semiconductor film because of crystallization of the semiconductor film. Thus, there are problems such as reduction in yield and increase in cost.

In addition, a thin film transistor including a microcrystalline germanium film has a problem of high off-current.

Furthermore, in the case where a microcrystalline semiconductor film is formed over a different material, crystallinity of the microcrystalline semiconductor film is low at the interface. Thus, an inverted staggered thin film transistor including a microcrystalline semiconductor film has problems in that the crystallinity of an interface region between a gate insulating film and a microcrystalline semiconductor film is low and electric characteristics of the thin film transistor are poor.

In view of the above problems, it is an object of the present invention to provide a thin film transistor having excellent electric characteristics, a display device including the thin film transistor, and a method for manufacturing the thin film transistor and the display device.

According to an aspect of the present invention, in a thin film transistor in which a microcrystalline germanium film, a gate insulating film in contact with one surface of the microcrystalline germanium film, and a gate electrode overlap with one another and a display device including the thin film transistor, a buffer layer is formed over the other surface of the microcrystalline germanium film.

As the buffer layer, an amorphous silicon film is given. Further, an amorphous silicon film including at least one of nitrogen, hydrogen, and halogen is also given. The buffer layer formed over the surface of the microcrystalline germanium film can reduce oxidation of crystal grains included in the microcrystalline germanium film, and serves as a high-resistance region, whereby off-current of the thin film transistor having the above structure can be reduced.

The buffer layer can be formed by a plasma CVD method, a sputtering method, or the like. Further, after an amorphous silicon film is formed, the surface of the amorphous silicon film is subjected to treatment with nitrogen plasma, hydrogen plasma, or halogen plasma, so that the amorphous silicon film is nitrided, hydrogenated, or halogenated.

In addition, a germanium film is formed over the gate insulating film, and then the germanium film is irradiated with plasma, whereby the germanium film is partly etched, and crystal nuclei having high crystallinity are formed at high density. Then, a microcrystalline germanium film with high crystallinity is formed over the gate insulating film by a plasma CVD method using a deposition gas including germanium, and hydrogen as a source gas.

As the germanium film formed over the gate insulating film, an amorphous germanium film or a microcrystalline germanium film is formed by a sputtering method, a CVD method, or the like.

As for the plasma for irradiating the germanium film, at least one of hydrogen, fluorine, and a fluoride is introduced to a reaction chamber of a plasma CVD apparatus, and high-frequency power is applied, whereby the plasma is generated. The plasma at least includes hydrogen plasma or fluorine plasma, and amorphous components of the germanium film are etched. In particular, in the case where the germanium film is a microcrystalline germanium film, crystal grains of the microcrystalline germanium film are small. Accordingly, amorphous components which fill spaces between the crystal grains are etched so that crystal nuclei having high crystallinity can be left at high density. In addition, in the case where the germanium film formed over the gate insulating film is an amorphous germanium film, amorphous components are etched and partly crystallized so that fine crystal nuclei can be formed at high density. Thus, since amorphous components at the interface with the gate insulating film are etched with plasma, crystal nuclei having high crystallinity can be formed over the gate insulating film.

Crystals are grown from crystal nuclei by a plasma CVD method using a deposition gas including germanium, and hydrogen as a source gas. Crystals grow in the direction of a normal line with respect to the surface of the gate insulating film, and thus, a microcrystalline germanium film which has column-like crystal grains closely connected with each other can be formed. Further, because crystals grow from crystal nuclei over the gate insulating film, a microcrystalline germanium film which has high crystallinity at the interface with the gate insulating film and also in the film itself can be formed. In addition, by using such a microcrystalline germanium film for a channel formation region of the thin film transistor, the thin film transistor can have high field-effect mobility and high on-current.

Note that, before the germanium film is formed over the gate insulating film, at least one of fluorine, a fluoride gas, and hydrogen is introduced to the reaction chamber of the plasma CVD apparatus, and high-frequency power is applied, whereby plasma is generated, so that the gate insulating film may be partly etched. Through the etching, the gate insulating film can have an uneven surface. The germanium film is formed over the gate insulating film having the uneven surface and the germanium film is exposed to plasma, whereby the density of crystal nuclei is easily increased, and a microcrystalline germanium film which has column-like crystal grains closely connected with each other can be formed.

In addition, an impurity element which serves as a donor may be added to the microcrystalline germanium film. By adding the impurity element which serves as a donor to the microcrystalline germanium film, the crystallinity of the microcrystalline germanium film, the conductivity of the microcrystalline germanium film, and the crystallinity of the microcrystalline germanium film at the interface with the gate insulating film can be improved. Therefore, by using a microcrystalline germanium film including the impurity element which serves as a donor for the channel formation region of the thin film transistor, the thin film transistor can have high field-effect mobility and high on-current.

In order to add the impurity element which serves as a donor to the microcrystalline germanium film, the impurity element which serves as a donor may be added to the gate insulating film, the germanium film, or the microcrystalline germanium film itself. In the case where the impurity element which serves as a donor is added to the gate insulating film, before the gate insulating film is formed, a gas including the impurity element which serves as a donor is supplied into a reaction chamber, whereby the impurity element which serves as a donor is adsorbed onto the inner wall of the reaction chamber and a base member of the gate insulating film. Alternatively, in addition to a source gas of the gate insulating film, a gas including the impurity element which serves as a donor may be introduced.

In the case where the impurity element which serves as a donor is added to the germanium film, before the germanium film is formed, a gas including the impurity element which serves as a donor is supplied into the reaction chamber, whereby the impurity element which serves as a donor may be adsorbed onto the inner wall of the reaction chamber and the gate insulating film. Alternatively, in addition to a source gas of the germanium film formed over the gate insulating film, a gas including the impurity element which serves as a donor may be introduced. Further alternatively, when the germanium film is etched, plasma may be generated using a gas including the impurity element which serves as a donor in addition to at least one of fluorine, a fluoride gas, and hydrogen, so that amorphous components in the germanium film formed over the gate insulating film may be etched with hydrogen radicals or fluorine radicals and the impurity element which serves as a donor may be added to the germanium film which is etched.

In the case where the impurity element which serves as a donor is added to the microcrystalline germanium film itself, before the microcrystalline germanium film is formed, a gas including the impurity element which serves as a donor is introduced, whereby the impurity element which serves as a donor may be adsorbed onto the inner wall of the reaction chamber, the gate insulating film, and the germanium film which is etched. Alternatively, in addition to a source gas of the microcrystalline germanium film, a gas including the impurity element which serves as a donor may be introduced.

Thin film transistors (TFTs) are manufactured using the microcrystalline germanium film of the present invention, and a display device is manufactured using the thin film transistors for a pixel portion and further for a driver circuit. Since the thin film transistor including the microcrystalline germanium film of the present invention has a field-effect mobility which is higher than that of a thin film transistor including an amorphous silicon film or a microcrystalline silicon film, a part of the driver circuit or the entire driver circuit can be formed over the same substrate as that of the pixel portion, so that a system-on-panel can be manufactured.

In addition, display devices include light-emitting devices and liquid crystal display devices. A light-emitting device includes a light-emitting element and a liquid crystal display device includes a liquid crystal element. A light-emitting element includes, in its category, an element whose luminance is controlled with current or voltage; specifically, an organic electroluminescent (EL) element and an inorganic EL element.

In addition, the display devices include a panel in which a display element is sealed, and a module in which an IC and the like including a controller are mounted on the panel. The present invention also relates to one mode of an element substrate before the display element is completed in a manufacturing process of the display device, and the element substrate is provided with a means for supplying current to the display element in each of a plurality of pixels. Specifically, the element substrate may be in a state of being provided with only a pixel electrode of the display element, a state after a conductive film to be a pixel electrode is formed and before the conductive film is etched to form the pixel electrode, or any other states.

A display device in this specification means an image display device, a light-emitting device, or a light source (including a lighting device). Further, the display device includes any of the following modules in its category: a module including a connector such as a flexible printed circuit (FPC), tape automated bonding (TAB) tape, or a tape carrier package (TCP); a module having TAB tape or a TCP which is provided with a printed wiring board at the end thereof; and a module having an integrated circuit (IC) which is directly mounted on a display element by a chip on glass (COG) method.

According to the present invention, by using a microcrystalline germanium film for a channel formation region, a thin film transistor with high field-effect mobility and high on-current can be manufactured. In addition, by providing a buffer layer between a microcrystalline germanium film functioning as a channel formation region and a source and drain regions, a thin film transistor with low off-current can be manufactured. In other words, a thin film transistor with excellent electric characteristics can be manufactured. Further, a display device including the thin film transistor can be manufactured.

### BRIEF DESCRIPTION OF THE DRAWINGS

FIG. 1 is a cross-sectional view illustrating a thin film transistor according to an aspect of the present invention.

FIG. 2 is a cross-sectional view illustrating a thin film transistor according to an aspect of the present invention.

FIG. 3 is a cross-sectional view illustrating a thin film transistor according to an aspect of the present invention.

FIGS. 4A to 4C are cross-sectional views illustrating a method for manufacturing a display device according to an aspect of the present invention.

FIGS. 5A to 5C are cross-sectional views illustrating a method for manufacturing a display device according to an aspect of the present invention.

FIGS. 6A and 6B are cross-sectional views illustrating a method for manufacturing a display device according to an aspect of the present invention.

FIGS. 7A to 7C are top views illustrating a method for manufacturing a display device according to an aspect of the present invention.

FIG. 8 is a drawing illustrating a structure of a plasma CVD apparatus applicable to the present invention.

FIGS. 9A to 9E are cross-sectional views illustrating a method for manufacturing a display device according to an aspect of the present invention.

FIGS. 10A to 10E are cross-sectional views illustrating a method for manufacturing a display device according to an aspect of the present invention.

FIGS. 11A to 11E are cross-sectional views illustrating a method for manufacturing a display device according to an aspect of the present invention.

FIGS. 12A and 12B are cross-sectional views illustrating a method for manufacturing a display device according to an aspect of the present invention.

FIGS. 13A to 13D are drawings illustrating multi-tone masks applicable to the present invention.

FIGS. 14A to 14C are cross-sectional views illustrating a method for manufacturing a display device according to an aspect of the present invention.

FIGS. 15A and 15B are cross-sectional views illustrating a method for manufacturing a display device according to an aspect of the present invention.

FIGS. 16A and 16B are cross-sectional views illustrating a method for manufacturing a display device according to an aspect of the present invention.

FIGS. 17A to 17C are cross-sectional views illustrating a method for manufacturing a display device according to an aspect of the present invention.

FIGS. 18A to 18C are top views illustrating a method for manufacturing a display device according to an aspect of the present invention.

FIG. 19 is a cross-sectional view illustrating a method for manufacturing a display device according to an aspect of the present invention.

FIG. 20 is a cross-sectional view illustrating a method for manufacturing a display device according to an aspect of the present invention.

FIG. 21 is a cross-sectional view illustrating a method for manufacturing a display device according to an aspect of the present invention.

FIG. 22 is a cross-sectional view illustrating a display device according to an aspect of the present invention.

FIG. 23 is a top view illustrating a display device according to an aspect of the present invention.

FIG. 24 is a top view illustrating a display device according to an aspect of the present invention.

FIGS. 25A and 25B are a top view and a cross-sectional view, respectively, illustrating a display device according to an aspect of the present invention.

FIGS. 26A to 26C are perspective views each illustrating a display panel according to an aspect of the present invention.

FIGS. 27A to 27C are perspective views each illustrating an electronic device having a display device according to an aspect of the present invention.

FIG. 28 is a diagram illustrating an electronic device including a display device according to an aspect of the present invention.

FIGS. 29A to 29C are drawings illustrating an electronic device including a display device according to an aspect of the present invention.

### DETAILED DESCRIPTION OF THE INVENTION

Hereinafter, embodiment modes of the present invention will be described with reference to the drawings. Note that the present invention is not limited to the following description, and it is easily understood by those skilled in the art that modes and details thereof can be modified in various ways without departing from the spirit and scope of the present invention. Thus, the present invention should not be interpreted as being limited to the following description of the embodiment modes. In the structures of the present invention to be described below, the reference numerals denoting the same portions are used in common in different drawings.

### Embodiment Mode 1

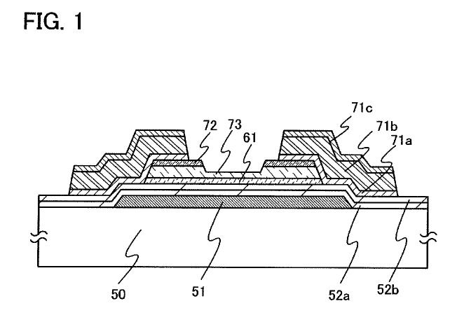

In a thin film transistor illustrated in FIG. 1, a gate electrode 51 is formed over a substrate 50, gate insulating films 52a and 52b are formed over the gate electrode 51, a microcrystalline germanium film 61 is formed over the gate insulating film 52b, a buffer layer 73 is formed over the microcrystalline germanium film 61, a pair of semiconductor films 72 to which an impurity element imparting one conductivity type is added are formed over the buffer layer 73, and wirings 71a to 71c are formed over the pair of semiconductor films 72 to which the impurity element imparting one conductivity type is added. The microcrystalline germanium film 61 formed over the gate insulating film 52b functions as a channel formation region of the thin film transistor and the buffer layer 73 functions as a high-resistance region.

For the substrate 50, an alkali-free glass substrate manufactured by a fusion method or a float method, such as a substrate of barium borosilicate glass, aluminoborosilicate glass, or aluminosilicate glass; a ceramic substrate; a plastic substrate which has high heat resistance enough to withstand a process temperature of this manufacturing process; or the like can be used. Further, a metal (e.g., stainless steel alloy) substrate whose surface is provided with an insulating film may be used.

The gate electrode 51 is formed of a metal material. As a metal material, aluminum, chromium, titanium, tantalum, molybdenum, copper, or the like is used. The gate electrode 51 is preferably formed of aluminum or a stacked-layer structure of aluminum and a barrier metal. As a barrier metal, a metal with a high-melting point, such as titanium, molybdenum, or chromium, is used. A barrier metal is preferably provided in order to prevent a hillock and oxidation of aluminum.

The gate electrode 51 is formed with a thickness of 50 to 300 nm inclusive. The thickness of 50 to 100 nm inclusive of the gate electrode 51 can prevent a disconnection of a microcrystalline germanium film and a wiring, which are formed later. Further, the thickness of 150 to 300 nm inclusive of the gate electrode 51 can lower the resistivity of the gate electrode 51 and increase the area of the substrate.

Since the microcrystalline germanium film and the wiring are formed over the gate electrode 51, the gate electrode 51 is preferably processed to have tapered end portions so that the microcrystalline germanium film and the wiring thereover are not disconnected. Further, although not illustrated, a wiring or a capacitor wiring which is connected to the gate electrode can also be formed at the same time when the gate electrode is formed.

The gate insulating films 52a and 52b can each be formed using a silicon oxide film, a silicon nitride film, a silicon oxynitride film, or a silicon nitride oxide film with a thickness of 50 to 150 nm. This embodiment mode shows an example in which a silicon nitride film or a silicon nitride oxide film is formed as the gate insulating film 52a, and a silicon oxide film or a silicon oxynitride film is formed as the gate insulating film 52b to form a stacked-layer structure. Instead of a two-layer structure, the gate insulating film can be formed using a single layer of a silicon oxide film, a silicon nitride film, a silicon oxynitride film, or a silicon nitride oxide film.

By forming the gate insulating film 52a using a silicon nitride film or a silicon nitride oxide film, adhesion between the substrate 50 and the gate insulating film 52a is increased, and further, an impurity from the substrate 50 can be prevented from diffusing into the microcrystalline germanium film 61 when a glass substrate is used for the substrate 50. Furthermore, oxidation of the gate electrode 51 can be prevented. That is to say, film peeling can be prevented, and electric characteristics of the thin film transistor which is completed later can be improved. Further, the gate insulating films 52a and 52b each having a thickness of greater than or equal to 50 nm are preferable because the gate insulating films 52a and 52b having the above thickness can alleviate reduction in coverage which is caused by unevenness due to the gate electrode 51.

Note that a silicon oxynitride film means a film that includes more oxygen than nitrogen, and includes oxygen, nitrogen, silicon, and hydrogen at concentrations ranging from 55 to 65 at. %, 1 to 20 at. %, 25 to 35 at. %, and 0.1 to 10 at. %, respectively. Further, a silicon nitride oxide film means a film that includes more nitrogen than oxygen, and includes oxygen, nitrogen, silicon, and hydrogen at concentrations ranging from 15 to 30 at. %, 20 to 35 at. %, 25 to 35 at. %, and 15 to 25 at. %, respectively.

The microcrystalline germanium film 61 is a film including germanium having an intermediate structure between amorphous and crystalline structures (including a single crystal and a polycrystal). This microcrystalline germanium film has a third state which is stable in free energy, and is a crystalline germanium film having short-range order and lattice distortion, and columnar or needle-like crystals with a grain diameter of 0.5 to 100 nm, preferably 1 to 20 nm have grown in a direction of the normal to the surface of the substrate. Further, amorphous germanium is present between a plurality of microcrystalline germanium.

The band gap of single crystal germanium is about 0.7 eV, and that of amorphous germanium is about 1.2 eV. Therefore, the band gap of a microcrystalline germanium film is higher than 0.7 eV and lower than 1.2 eV. On the other hand, the band gap of single crystal silicon is 1.1 eV, and that of amorphous silicon is about 1.7 eV. Therefore, the band gap of a microcrystalline silicon film is higher than 1.1 eV and lower than 1.7 eV. Since single crystal germanium has lower resistivity and higher mobility than single crystal silicon, a thin film transistor using a microcrystalline germanium film for a channel formation region has higher field-effect mobility and higher on-current than a thin film transistor using a microcrystalline silicon film for a channel formation region.

The microcrystalline germanium film 61 is formed to have a thickness of 1 to 200 nm inclusive, preferably 1 to 80 nm inclusive, more preferably 5 to 30 nm inclusive. When at least the microcrystalline germanium film 61 is formed with a thickness of 1 to 50 nm inclusive, the thin film transistor can be a complete depletion type.

Further, it is preferable that the concentration of oxygen and the concentration of nitrogen in the microcrystalline germanium film each be lower than 3×10¹⁹ atoms/cm³, preferably lower than 3×10¹⁸ atoms/cm³; and that the concentration of carbon be less than or equal to 3×10¹⁸ atoms/cm³. Lower concentration of oxygen, nitrogen, or carbon in the microcrystalline germanium film can suppress generation of defects in the microcrystalline germanium film. Furthermore, oxygen or nitrogen in the microcrystalline germanium film hinders crystallization. Therefore, when the microcrystalline germanium film includes oxygen or nitrogen at relatively low concentration, the crystallinity of the microcrystalline germanium film can be improved.

In addition, by adding an impurity element which serves as an acceptor to the microcrystalline germanium film of this embodiment mode at the same time as or after formation of the microcrystalline germanium film, the threshold voltage can be controlled. A typical example of the impurity element which serves as an acceptor is boron, and an impurity gas such as B₂H₆ or BF₃ is preferably mixed at 1 to 1000 ppm, preferably at 1 to 100 ppm, into a deposition gas including germanium. The concentration of boron is preferably set to be 1×10¹⁴ to 6×10¹⁶ atoms/cm³, for example.

An amorphous silicon film, an amorphous silicon film including halogen such as fluorine or chlorine, or an amorphous silicon film including nitrogen is used as the buffer layer 73. The buffer layer 73 has a thickness of 50 to 200 nm.

The buffer layer 73, which is formed of an amorphous silicon film, has a larger energy gap and a higher resistivity than the microcrystalline germanium film 61, and further, mobility in the buffer layer 73 is lower than that in the microcrystalline germanium film 61. In the thin film transistor which is formed later, therefore, the buffer layer 73 functions as a high-resistance region and thus can reduce leak current which is generated between the semiconductor films 72 which function as a source and drain regions and the microcrystalline germanium film 61. Further, off-current can be reduced.

By formation of an amorphous silicon film, moreover, an amorphous silicon film including hydrogen, nitrogen, or halogen as the buffer layer 73 over the surface of the microcrystalline germanium film 61, surfaces of crystal grains included in the microcrystalline germanium film 61 can be prevented from being naturally oxidized. In particular, in a region where amorphous germanium is in contact with microcrystalline germanium, a crack is likely to be caused due to local stress. When this crack is exposed to oxygen, the microcrystalline germanium is oxidized. However, by formation of the buffer layer 73 over the surface of the microcrystalline germanium film 61, the microcrystalline germanium can be prevented from being oxidized.

If an n-channel thin film transistor is formed, the semiconductor films 72 to which the impurity element imparting one conductivity type is added may be doped with phosphorus, which is a typical impurity element; for example, an impurity gas such as PH₃ may be added to a deposition gas including silicon. If a p-channel thin film transistor is formed, the semiconductor films 72 to which the impurity element imparting one conductivity type is added may be doped with boron, which is a typical impurity element; for example, an impurity gas such as B₂H₆ may be added to a deposition gas including silicon. The semiconductor films 72 to which the impurity element imparting one conductivity type is added include phosphorus or boron at a concentration of 1×10¹⁹ to 1×10²¹ atoms/cm³, thereby having ohmic contact with the conductive film, and the semiconductor films 72 to which the impurity element imparting one conductivity type is added function as a source and drain regions. The semiconductor films 72 to which the impurity element imparting one conductivity type is added can be formed using a microcrystalline silicon film or an amorphous silicon film. The semiconductor films 72 to which the impurity element imparting one conductivity type is added are formed with a thickness of 5 to 50 nm inclusive. Reduction in the thickness of the semiconductor film to which the impurity element imparting one conductivity type is added can improve the throughput.

The wirings 71a to 71c are preferably formed with a single layer or stacked layers using aluminum; copper; or an aluminum alloy to which an element for preventing a migration, an element for improving a heat resistance property, or an element for preventing a hillock, such as copper, silicon, titanium, neodymium, scandium, or molybdenum, is added. Alternatively, a film in contact with the semiconductor film to which the impurity element imparting one conductivity type is added may be formed of titanium, tantalum, molybdenum, or tungsten, or a nitride of such an element; and aluminum or an aluminum alloy may be formed thereover to form a stacked-layer structure. Further alternatively, top and bottom surfaces of aluminum or an aluminum alloy may be each covered with titanium, tantalum, molybdenum, or tungsten, or a nitride of such an element to form a stacked-layer structure. This embodiment mode shows a structure in which three conductive films are stacked as the wirings 71a to 71c, and a stacked-layer structure in which the wirings 71a and 71c are formed using molybdenum films and the wiring 71b is formed using an aluminum film, or a stacked-layer structure in which the wirings 71a and 71c are formed using titanium films and the wiring 71b is formed using an aluminum film is formed.

As described in this embodiment mode, a thin film transistor using a microcrystalline germanium film for a channel formation region can have higher field-effect mobility and higher on-current than a thin film transistor using a microcrystalline silicon film or an amorphous silicon film for a channel formation region. In addition, a buffer layer between a microcrystalline germanium film functioning as a channel formation region and a source and drain regions, which is formed of an amorphous silicon film with high resistivity, functions as a high-resistance region and can reduce off-current of the thin film transistor. Therefore, in the thin film transistor, an ON/OFF ratio and field-effect mobility can be increased, and electric characteristics can be improved.

### Embodiment Mode 2

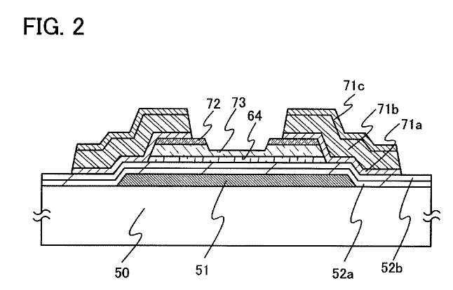

In this embodiment mode, a thin film transistor including a microcrystalline germanium film which has higher mobility than that of Embodiment Mode 1 will be described with reference to FIG. 2.

In a thin film transistor illustrated in FIG. 2, a gate electrode 51 is formed over a substrate 50, gate insulating films 52a and 52b are formed over the gate electrode 51, a microcrystalline germanium film 64 including an impurity element which serves as a donor is formed over the gate insulating film 52b, a buffer layer 73 is formed over the microcrystalline germanium film 64 including the impurity element which serves as a donor, a pair of semiconductor films 72 to which an impurity element imparting one conductivity type is added are formed over the buffer layer 73, and wirings 71a to 71c are formed over the pair of semiconductor films 72 to which the impurity element imparting one conductivity type is added. The microcrystalline germanium film 64 formed over the gate insulating film 52b functions as a channel formation region and the buffer layer 73 functions as a high-resistance region.

The microcrystalline germanium film 64 including the impurity element which serves as a donor includes the impurity element which serves as a donor at a concentration of 6×10¹⁵ to 3×10¹⁸ atoms/cm³ inclusive, preferably 3×10¹⁶ to 3×10¹⁷ atoms/cm³ inclusive, which is measured by secondary ion mass spectrometry (SIMS). The impurity element which serves as a donor is phosphorus, arsenic, antimony, or the like.

The concentration of the impurity element which serves as a donor and is included in the microcrystalline germanium film 64 is set to be in the above range, whereby the interface between the gate insulating film 52b and the microcrystalline germanium film 64 including the impurity element which serves as a donor can have improved crystallinity and the microcrystalline germanium film 64 including the impurity element which serves as a donor can have lower resistivity; thus, the thin film transistor including the microcrystalline germanium film 64 in a channel formation region has high field-effect mobility and high on-current. When the peak concentration of the impurity element which serves as a donor and is included in the microcrystalline germanium film 64 is lower than 6×10¹⁵ atoms/cm³, the amount of the impurity element which serves as a donor is insufficient, and thus increase in the field-effect mobility and in the on-current cannot be expected. Further, when the peak concentration of the impurity element which serves as a donor and is included in the microcrystalline germanium film 64 is higher than 3×10¹⁸ atoms/cm³, the threshold voltage shifts to the minus side of the gate voltage, and the transistor does not function well; therefore, it is preferable that the concentration of the impurity element which serves as a donor be 6×10¹⁵ to 3×10¹⁸ atoms/cm³ inclusive, more preferably 3×10¹⁶ to 3×10¹⁷ atoms/cm³ inclusive.

In this embodiment mode, only the microcrystalline germanium film 64 includes the impurity element which serves as a donor, but the gate insulating film 52a or the gate insulating film 52b may also include the impurity element which serves as a donor. When the gate insulating film 52a or 52b includes the impurity element which serves as a donor, the impurity element which serves as a donor is deposited on the surface of the gate insulating film. When the impurity element which serves as a donor is deposited on the surface of the gate insulating film 52b, crystallinity of the microcrystalline germanium film 64 which starts to be deposited can be increased. When the gate insulating film on the gate electrode side includes the impurity element which serves as a donor, the impurity element can be diffused into the gate insulating film on the microcrystalline germanium film 64 side at a low concentration.

Accordingly, crystallinity at the interface between the gate insulating film 52b and the microcrystalline germanium film 64 can be improved and resistivity of the microcrystalline germanium film 64 can be reduced. Thus, the thin film transistor can have higher field-effect mobility and higher on-current.

### Embodiment Mode 3

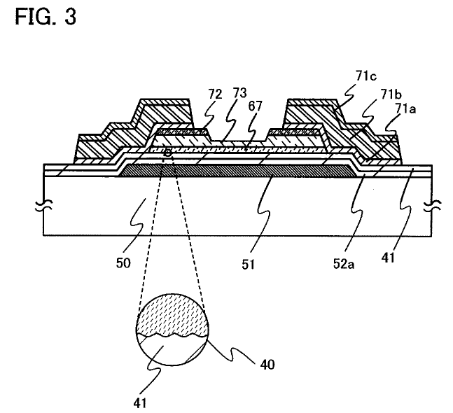

In this embodiment mode, a thin film transistor including a microcrystalline germanium film which can have higher field-effect mobility and provide higher yield, compared to Embodiment Mode 1, will be described with reference to FIG. 3.

In a thin film transistor illustrated in FIG. 3, a gate electrode 51 is formed over a substrate 50, a gate insulating film 52a is formed over the gate electrode 51, a gate insulating film 41 having an uneven surface is formed over the gate insulating film 52a, a microcrystalline germanium film 67 is formed over the gate insulating film 41, a buffer layer 73 is formed over the microcrystalline germanium film 67, a pair of semiconductor films 72 to which an impurity element imparting one conductivity type is added are formed over the buffer layer 73, and wirings 71a to 71c are formed over the pair of semiconductor films 72 to which the impurity element imparting one conductivity type is added. The microcrystalline germanium film 67 formed over the gate insulating film 41 functions as a channel formation region and the buffer layer 73 functions as a high-resistance region.

As illustrated in an enlarged view 40, projections and depressions are formed on the uneven surface of the gate insulating film 41. Each of the projections and depressions may have a wavelike shape with a gentle curve to form the uneven shape. Alternatively, the projections may have a sharp needle-like shape and the depressions may have a gently curved shape. The height difference between the top of the projection and the bottom of the depression is several nm to several tens of nm. Since the surface of the gate insulating film 41 is uneven, adhesion between the gate insulating film 41 and the microcrystalline germanium film 67 is improved. Therefore, separation at the interface between the gate insulating film 41 and the microcrystalline germanium film 67 can be reduced in a manufacturing process of the thin film transistor, and the yield can be increased. In addition, by using the microcrystalline germanium film 67 for a channel formation region, a thin film transistor with high field-effect mobility and high on-current can be manufactured.

### Embodiment Mode 4

In this embodiment mode, a manufacturing process of the thin film transistor described in Embodiment Mode 1 will be described.

It is desired that all thin film transistors formed over the same substrate have the same polarity, in order to reduce the number of manufacturing steps. Here, description is made using an n-channel thin film transistor.

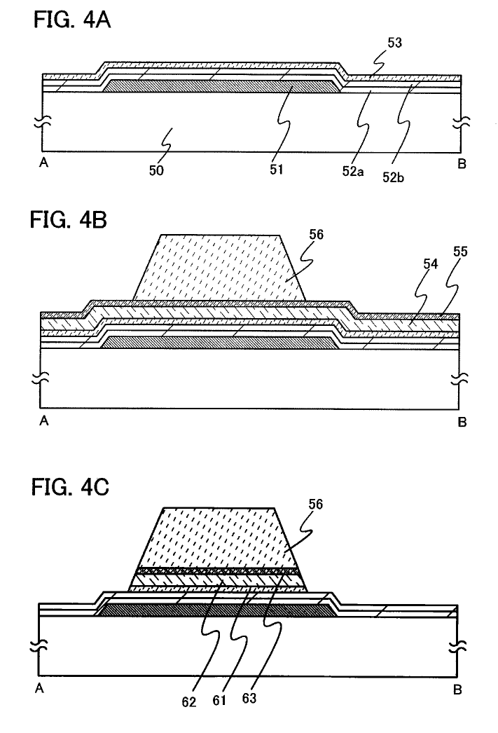

As illustrated in FIG. 4A, a gate electrode 51 is formed over a substrate 50, and gate insulating films 52a and 52b are formed over the gate electrode 51.

The gate electrode 51 is formed by a sputtering method, a CVD method, a plating method, a printing method, a droplet discharge method, or the like using any of the metal materials for the gate electrode 51 described in Embodiment Mode 1. In this embodiment mode, a molybdenum film is formed as a conductive film over the substrate 50 by a sputtering method and is etched by use of a resist mask which is formed using a first photomask, whereby the gate electrode 51 is formed.

Each of the gate insulating films 52a and 52b can be formed by a CVD method, a sputtering method, or the like using a silicon oxide film, a silicon nitride film, a silicon oxynitride film, or a silicon nitride oxide film. This embodiment mode shows an example in which a silicon nitride film or a silicon nitride oxide film is formed as the gate insulating film 52a, and a silicon oxide film or a silicon oxynitride film is formed thereover as the gate insulating film 52b to form a stacked-layer structure.

Next, a microcrystalline germanium film 53 is formed over the gate insulating film 52b by a CVD method using a deposition gas including germanium, and hydrogen. A rare gas may be used, in addition to a deposition gas including germanium, and hydrogen. Examples of a deposition gas including germanium are germane (GeH₄), digermane (Ge₂H₆), trigermane (Ge₃H₈), and the like. A deposition gas including germanium, here, germane, and hydrogen, and/or a rare gas are mixed, to form the microcrystalline germanium film by glow discharge plasma. Germane is diluted with hydrogen and/or a rare gas to be 10 to 2000 times thinner. The substrate heating temperature is 100 to 400° C., preferably 250 to 350° C.

In the process for forming the microcrystalline germanium film 53, glow discharge plasma is generated by applying high-frequency power with a frequency of 1 to 30 MHz, typically 13.56 MHz or 27.12 Mz, or high-frequency power with a frequency in the VHF band of 30 to about 300 MHz, typically 60 MHz.

Further, it is preferable that the concentration of oxygen and the concentration of nitrogen in the microcrystalline germanium film 53 each be lower than 3×10¹⁹ atoms/cm³, preferably lower than 3×10¹⁸ atoms/cm³; and that the concentration of carbon be less than or equal to 3×10¹⁸ atoms/cm³. Lower concentration of oxygen, nitrogen, or carbon in the microcrystalline germanium film can suppress generation of defects in the microcrystalline germanium film. Furthermore, oxygen or nitrogen in the microcrystalline germanium film hinders crystallization. Therefore, when the microcrystalline germanium film includes oxygen or nitrogen at relatively low concentration, the crystallinity of the microcrystalline germanium film can be improved.

In addition to a deposition gas including germanium, and hydrogen, fluorine or a fluoride may be used. Examples of a fluoride include HF, GeF₄, GeHF₃, GeH₂F₂, GeH₃F, Ge₂F₆, and the like. By using fluorine or a fluoride, amorphous germanium components in a region where crystals grow are etched with fluorine radicals, so that crystal growth providing high crystallinity can be achieved. In other words, a microcrystalline germanium film with high crystallinity can be formed.

In addition to a deposition gas including germanium, and hydrogen, a deposition gas including silicon typified by silane, disilane, or trisilane may be used, and a semiconductor film whose main component is germanium and which includes silicon may be formed instead of the microcrystalline germanium film.

By adding an impurity element which serves as an acceptor to the microcrystalline germanium film of this embodiment mode which functions as a channel formation region of the thin film transistor at the same time as or after formation of the microcrystalline germanium film, the threshold voltage can be controlled. A typical example of the impurity element which serves as an acceptor is boron, and an impurity gas such as B₂H₆ or BF₃ is preferably mixed at 1 to 1000 ppm, preferably at 1 to 100 ppm, into a deposition gas including germanium. The concentration of boron is preferably set to be 1×10¹⁴ to 6×10¹⁶ atoms/cm³.

Next, a buffer layer 54 and a semiconductor film 55 to which an impurity element imparting one conductivity type is added are formed over the microcrystalline germanium film 53 as illustrated in FIG. 4B. Then, a resist mask 56 is formed over the semiconductor film 55 to which the impurity element imparting one conductivity type is added.

As the buffer layer 54, an amorphous silicon film can be formed by a plasma CVD method using a deposition gas including silicon. In addition, by dilution of a deposition gas including silicon with one or plural kinds of rare gas elements selected from helium, argon, krypton, or neon, an amorphous silicon film can be formed. Furthermore, an amorphous silicon film including hydrogen can be formed using hydrogen with a flow rate of 1 to 10 times, preferably 1 to 5 times as high as that of a deposition gas including silicon. In addition, halogen such as fluorine or chlorine may be added to the above amorphous silicon film.

As the buffer layer 54, an amorphous silicon film can also be formed by sputtering with hydrogen or a rare gas, using silicon as a target.

In some cases, the buffer layer 54 is partly etched in a later step of forming a source and drain regions. Thus, the buffer layer 54 is preferably formed with such a thickness that a part of the buffer layer 54 is left at that time. Typically, it is preferable to form the buffer layer 54 with a thickness of 50 to 200 nm inclusive. In a display device including a thin film transistor to which a high voltage (e.g., about 15 V) is applied, typically, in a liquid crystal display device, if the buffer layer 54 is formed thickly, drain withstand voltage is increased, so that deterioration of the thin film transistor can be reduced even if a high voltage is applied to the thin film transistor.

Formation of an amorphous silicon film or an amorphous silicon film including hydrogen, nitrogen, or halogen over the surface of the microcrystalline germanium film 53 can prevent surfaces of crystal grains included in the microcrystalline germanium film 53 from being naturally oxidized. In particular, in a region where amorphous germanium is in contact with microcrystal grains, a crack is likely to be caused due to local stress. When this crack is exposed to oxygen, the crystal grains are oxidized, whereby germanium oxide is formed. However, by formation of the buffer layer 54 over the surface of the microcrystalline germanium film 53, the microcrystal grains can be prevented from being oxidized.

Since the buffer layer 54 is formed using an amorphous silicon film or an amorphous silicon film including hydrogen or halogen, the buffer layer 54 has a larger energy gap, higher resistivity, and lower mobility than the microcrystalline germanium film 53. Therefore, in a thin film transistor to be formed later, the buffer layer formed between a source and drain regions and the microcrystalline germanium film 53 functions as a high-resistance region and the microcrystalline germanium film 53 functions as a channel formation region. Accordingly, off-current of the thin film transistor can be reduced. In addition, when the thin film transistor is used as a switching element of a display device, the display device can have an improved contrast.

The buffer layer 54 is preferably formed at temperatures of 300 to 400° C. by a plasma CVD method after forming the microcrystalline germanium film 53. By this treatment, hydrogen is supplied to the microcrystalline germanium film 53, and the same effect as hydrogenating the microcrystalline germanium film 53 can be obtained. In other words, by depositing the buffer layer 54 over the microcrystalline germanium film 53, hydrogen is diffused into the microcrystalline germanium film 53, and a dangling bond can be terminated.

If an n-channel thin film transistor is formed, the semiconductor film 55 to which the impurity element imparting one conductivity type is added may be doped with phosphorus, which is a typical impurity element; for example, an impurity gas such as PH₃ may be added to a deposition gas including silicon. If a p-channel thin film transistor is formed, the semiconductor film 55 to which the impurity element imparting one conductivity type is added may be doped with boron, which is a typical impurity element; for example, an impurity gas such as B₂H₆ may be added to a deposition gas including silicon. The semiconductor film 55 to which the impurity element imparting one conductivity type is added includes phosphorus or boron at a concentration of 1×10¹⁹ to 1×10²¹ atoms/cm³, thereby having ohmic contact with wirings 71a to 71c, and the semiconductor film 55 to which the impurity element imparting one conductivity type is added functions as a source and drain regions. The semiconductor film 55 to which the impurity element imparting one conductivity type is added can be formed using a microcrystalline silicon film or an amorphous silicon film with a thickness of 5 to 50 nm inclusive. Reduction in the thickness of the semiconductor film to which the impurity element imparting one conductivity type is added can improve the throughput.

Then, the resist mask 56 is formed over the semiconductor film 55 to which the impurity element imparting one conductivity type is added.

The resist mask 56 is formed by a photolithography technique. Here, using a second photomask, the resist mask 56 is formed by exposing a resist that is applied on the semiconductor film 55 to which the impurity element imparting one conductivity type is added to light and developing the resist.

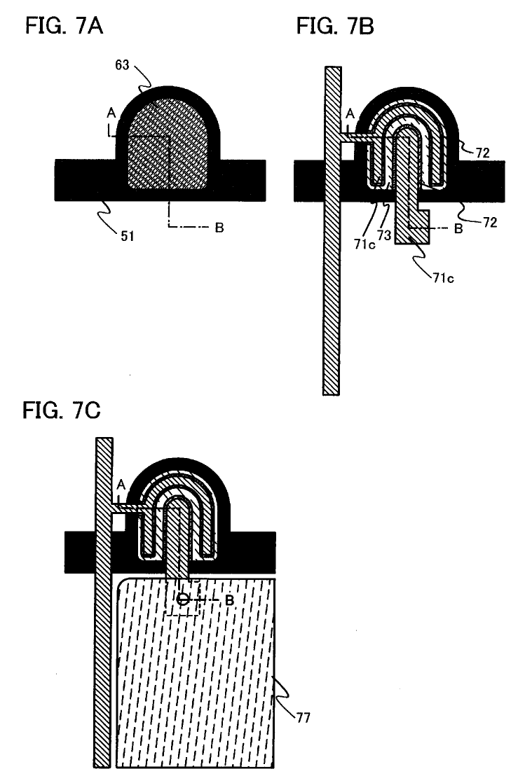

Next, the microcrystalline germanium film 53, the buffer layer 54, and the semiconductor film 55 to which the impurity element imparting one conductivity is added are etched using the resist mask 56, whereby a microcrystalline germanium film 61, a buffer layer 62, and a semiconductor film 63 to which the impurity element imparting one conductivity type is added are formed as illustrated in FIG. 4C. After that, the resist mask 56 is removed. FIG. 4C illustrates a cross section taken along a line A-B in FIG. 7A (except for the resist mask 56).

With side surfaces of end portions of the microcrystalline germanium film 61 and the buffer layer 62 having inclines, the microcrystalline germanium film 61 and a source and drain regions formed over the buffer layer 62 have a larger distance therebetween, so that leak current between the microcrystalline germanium film 61 and the source and drain regions can be prevented. In addition, leak current between the wirings and the microcrystalline germanium film 61 can also be prevented. The inclination angle of the side surfaces of the end portions of the microcrystalline germanium film 61 and the buffer layer 62 is 30° to 90°, preferably 45° to 80°. With such an angle, disconnection of the wirings due to a step shape can be prevented.

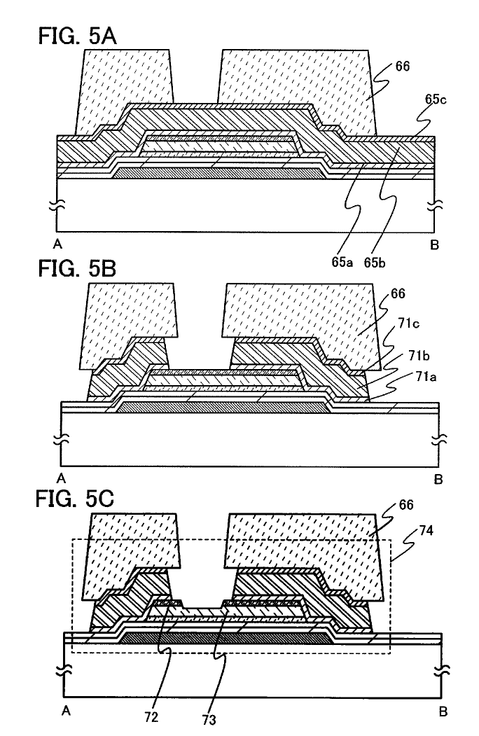

Next, as illustrated in FIG. 5A, conductive films 65a to 65c are formed over the semiconductor film 63 to which the impurity element imparting one conductivity type is added and the gate insulating film 52b, and then, a resist mask 66 is formed over the conductive films 65a to 65c. The conductive films 65a to 65 are formed by a sputtering method, a CVD method, a printing method, a droplet discharge method, an evaporation method, or the like using any of the materials for the wirings 71a to 71c described in Embodiment Mode 1 as appropriate. Here, as the conductive film, a conductive film having a three-layer structure in which the conductive films 65a to 65c are stacked is illustrated; a molybdenum film is used for each of the conductive films 65a and 65c and an aluminum film is used for the conductive film 65b, or a titanium film is used for each of the conductive films 65a and 65c and an aluminum film is used for the conductive film 65b. The conductive films 65a to 65c are formed by a sputtering method or a vacuum evaporation method.

The resist mask 66 can be formed in a similar manner to the resist mask 56.

Next, as illustrated in FIG. 5B, the conductive films 65a to 65c are partly etched to form pairs of the wirings 71a to 71c (functioning as a source and drain electrodes). Here, the conductive films 65a to 65c are etched by wet etching using the resist mask 66 that is formed by a photolithography process using a third photomask, so that the conductive films 65a to 65c are isotropically etched. Consequently, the wirings 71a to 71c, which have smaller areas than the resist mask 66, can be formed.

Then, the semiconductor film 63 to which the impurity element imparting one conductivity type is added is etched to be separated using the resist mask 66. As a result, a pair of semiconductor films 72 functioning as a source and drain regions can be formed as illustrated in FIG. 5C. In this etching process, the buffer layer 62 is also partly etched. The buffer layer which is etched partly and has a recessed portion is referred to as a buffer layer 73. The source and drain regions and the recessed portion of the buffer layer can be formed in the same process. The depth of the recessed portion in the buffer layer is set to half to one third the thickness of the thickest region in the buffer layer, so that the source region and the drain region can have a distance therebetween. Accordingly, leak current between the source region and the drain region can be reduced. After that, the resist mask 66 is removed.

Next, dry etching may be performed under such a condition that the buffer layer which is exposed is not damaged and an etching rate with respect to the buffer layer is low. Through this dry etching step, an etching residue on the buffer layer between the source region and the drain region, a residue of the resist mask, and a contamination source in the apparatus used for removal of the resist mask can be removed, whereby the source region and the drain region can be certainly insulated. As a result, leak current of the thin film transistor can be reduced, so that a thin film transistor with small off-current and high withstand voltage can be manufactured. A chlorine gas can be used for an etching gas, for example.

FIG. 5C illustrates a cross section taken along a line A-B in FIG. 7B (except for the resist mask 66). As illustrated in FIG. 7B, end portions of the semiconductor films 72 functioning as a source and drain regions are located outside those of the wirings 71c. Further, end portions of the buffer layer 73 are located outside those of the wirings 71c and those of the semiconductor films 72 functioning as a source and drain regions. Furthermore, one of the wirings surrounds the other (specifically, the former wiring is in a U-shape or a C-shape). Thus, an area of a region in which carriers move can be increased, and thus, the amount of current can be increased and an area of a thin film transistor can be reduced. Over the gate electrode, the microcrystalline germanium film and the wirings are overlapped, and thus, an influence by unevenness due to the gate electrode is small and reduction in coverage and generation of leak current can be suppressed.

Through the above-described process, a channel-etched thin film transistor 74 can be formed.

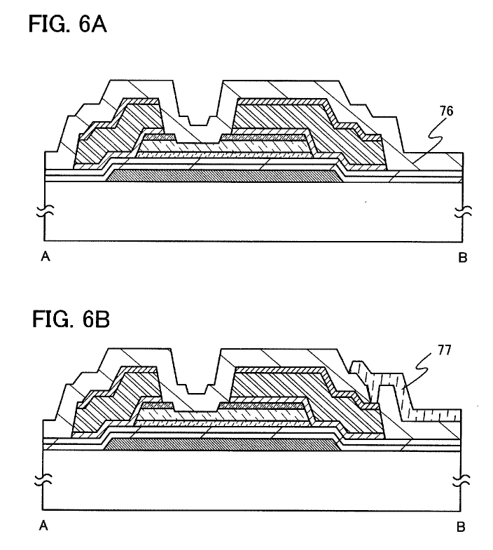

Next, as illustrated in FIG. 6A, a protective insulating film 76 is formed over the wirings 71a to 71c, the semiconductor films 72 functioning as a source and drain regions, the buffer layer 73, and the gate insulating film 52b. The protective insulating film 76 can be formed in a similar manner to the gate insulating films 52a and 52b. The protective insulating film 76 prevents intrusion of a contaminating impurity such as an organic matter, a metal, or water vapor included in the air; thus, a dense film is preferably used for the protective insulating film 76. Further, by using a silicon nitride film as the protective insulating film 76, the oxygen concentration in the buffer layer 73 can be set at less than or equal to 5×10¹⁹ atoms/cm³, preferably, less than or equal to 1×10¹⁹ atoms/cm³, so that the buffer layer 73 can be prevented from being oxidized.

Next, as illustrated in FIG. 6B, a contact hole is formed in the protective insulating film 76 by partly etching the protective insulating film 76 with the use of a resist mask formed using a fourth photomask, and then, a pixel electrode 77 that is in contact with the wiring 71c in the contact hole is formed. FIG. 6B illustrates a cross section taken along a line A-B in FIG. 7C. The wirings 71a to 71c which are connected to the pixel electrode 77 of a display element serve as a drain electrode, and the wirings 71a to 71c which face the wirings serving as a drain electrode serve as a source electrode (a source wiring), whereby on-current of the thin film transistor can be increased and deterioration due to repeated operations can be reduced. In addition, parasitic capacitance is not easily generated between the gate electrode 51 and the wirings 71a to 71c serving as a drain electrode and electric charge can easily be accumulated in the pixel electrode 77. Therefore, when the thin film transistor is used for a liquid crystal display device, a liquid crystal element can be operated at high speed.

The pixel electrode 77 can be formed of a light-transmitting conductive material such as indium oxide including tungsten oxide, indium zinc oxide including tungsten oxide, indium oxide including titanium oxide, indium tin oxide including titanium oxide, ITO, indium zinc oxide, or indium tin oxide to which silicon oxide is added.

In addition, the pixel electrode 77 can be formed using a conductive composition including a conductive high-molecular compound (also referred to as a conductive polymer). It is preferable that a pixel electrode formed using a conductive composition have sheet resistance of less than or equal to 10000 Ω/square, and light transmittance of greater than or equal to 70% at a wavelength of 550 nm. In addition, the resistivity of the conductive high-molecular compound which is included in the conductive composition is desirably less than or equal to 0.1 Ω-cm.

As the conductive high-molecular compound, a so-called n electron conjugated conductive high-molecular compound can be used. Examples thereof include polyaniline and its derivatives, polypyrrole and its derivatives, polythiophene and its derivatives, and copolymers of two or more kinds of them.

In this embodiment mode, the pixel electrode 77 is formed as follows: an ITO film is formed by a sputtering method, a resist is applied on the ITO film and exposed to light and developed using a fifth photomask, thereby forming a resist mask, and then, the ITO film is etched using the resist mask.

Accordingly, a thin film transistor and an element substrate that can be used for a display device can be formed.

In the film formation treatment of the microcrystalline germanium film, helium may be added to a reaction gas, in addition to a deposition gas including germanium, and hydrogen. Since helium has an ionization energy of 24.5 eV that is the highest among all gases, and has a metastable state in the level of about 20 eV that is a little lower than the ionization energy, only the difference of about 4 eV is necessary for ionization while keeping discharge. Therefore, the discharge starting voltage also shows the lowest value among all gases. By such characteristics, plasma can be held stably with helium. Further, since uniform plasma can be formed with helium, even if the area of a substrate over which a microcrystalline germanium film is deposited is large, an effect of making plasma density uniform can be obtained.

A thin film transistor using a microcrystalline germanium film has higher field-effect mobility and higher on-current than a thin film transistor using an amorphous silicon film or a microcrystalline silicon film. Thus, with the use of a thin film transistor, a channel formation region of which is formed of a microcrystalline germanium film, for switching of a display element, the area of the channel formation region, that is, the area of the thin film transistor can be decreased. Accordingly, the area of the thin film transistor in a single pixel is reduced, and thus, the aperture ratio of the pixel can be increased. Accordingly, the display device can have high definition.

Since the channel formation region of the thin film transistor manufactured in this embodiment mode is formed using a microcrystalline germanium film, resistivity thereof is lower than that of the channel formation region formed using an amorphous silicon film. Therefore, the thin film transistor using the microcrystalline germanium film 61 has current-voltage characteristics represented by a curve with a steep slope in a rising portion, has an excellent response as a switching element, and can be operated at high speed. Further, forming the channel formation region of the thin film transistor with the microcrystalline germanium film suppresses variation in threshold voltage of the thin film transistor, improves field-effect mobility, and lowers subthreshold swing (S value); thus, the thin film transistor can achieve high performance. Accordingly, a driving frequency of a display device can be increased, whereby the panel size can be increased and high density of pixels can be achieved.

Further, in the thin film transistor manufactured in this embodiment mode, an amorphous silicon film with high resistivity is formed as the buffer layer between the microcrystalline germanium film which functions as a channel formation region and the semiconductor films to which the impurity element imparting one conductivity type is added and which function as a source and drain regions. Off-current flows through the buffer region. However, because the buffer layer is a high-resistance region, the amount of off-current flowing therethrough can be suppressed, and furthermore, the microcrystalline germanium film can be prevented from being oxidized. Accordingly, off-current can be suppressed, and increase in on-current which is due to reduction of defects in the channel formation region can be realized. Furthermore, deterioration with time can be decreased.

Next, as an example of a plasma CVD apparatus applicable to the film formation process of this embodiment mode, an example of a structure which is suitable for deposition of a gate insulating film, a microcrystalline germanium film, a buffer layer, and a semiconductor film to which an impurity element imparting one conductivity type is added will be described.

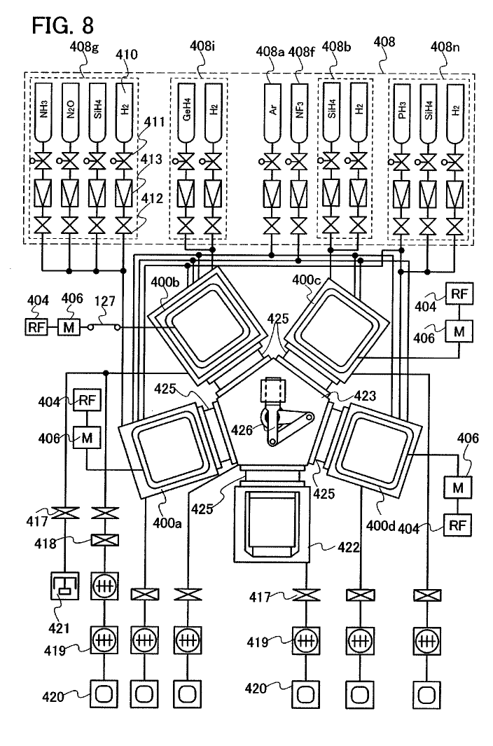

FIG. 8 illustrates an example of a multi-chamber plasma CVD apparatus including a plurality of reaction chambers. The apparatus is provided with a common chamber 423, a load/unload chamber 422, a first reaction chamber 400a, a second reaction chamber 400b, a third reaction chamber 400c, and a fourth reaction chamber 400d. This apparatus is a single wafer-processing type in which a substrate set in a cassette in the load/unload chamber 422 is transferred to/from each reaction chamber by a transfer unit 426 in the common chamber 423. A gate valve 425 is provided between the common chamber 423 and each chamber such that treatments performed in different reaction chambers do not interfere each other.

Each reaction chamber is used for a different purpose, depending on the kinds of thin films to be formed. For example, an insulating film such as a gate insulating film is formed in the first reaction chamber 400a, a microcrystalline germanium film which becomes a channel formation region of a thin film transistor is formed in the second reaction chamber 400b, a buffer layer which becomes a high-resistance region of the thin film transistor is formed in the third reaction chamber 400c, and a semiconductor film to which an impurity element imparting one conductivity type is added and which forms a source and a drain is formed in the fourth reaction chamber 400d. Of course, the number of the reaction chambers is not limited to four, and can be increased or decreased as needed. One film may be formed in one reaction chamber, or a plurality of films may be formed in one reaction chamber.

A turbo-molecular pump 419 and a dry pump 420 are connected to each reaction chamber as exhaust units. The exhaust units are not limited to a combination of these vacuum pumps and can employ other vacuum pumps as long as they can evacuate the reaction chamber to a degree of vacuum of about 10⁻¹ to 10⁻⁵ Pa. A butterfly valve 417 is provided between the exhaust units and each reaction chamber, which can interrupt vacuum evacuation, and a conductance valve 418 can control evacuation speed to adjust the pressure in each reaction chamber.

Note that the second reaction chamber 400b in which a microcrystalline germanium film is formed may be connected to a cryopump 421 which performs vacuum evacuation to an ultra-high vacuum. By use of the cryopump 421, the reaction chamber can be evacuated to an ultra-high vacuum with a pressure of lower than 10⁻⁵ Pa. In this embodiment mode, with an ultra-high vacuum with a pressure of lower than 10⁻⁵ Pa in the reaction chamber, the oxygen concentration and the nitrogen concentration in the microcrystalline germanium film can be effectively reduced. Consequently, the oxygen concentration in the microcrystalline germanium film can be set at less than or equal to 1×10¹⁶ atoms/cm³. With the reduced oxygen concentration and nitrogen concentration in the microcrystalline germanium film, defects in the film can be reduced, whereby crystallinity can be improved and thus carrier mobility can be improved.

A gas supply unit 408 includes a cylinder 410 filled with a gas used for the process, such as a rare gas or a semiconductor source gas typified by silane or germane, a stop valve 412, a mass flow controller 413, and the like. A gas supply unit 408g is connected to the first reaction chamber 400a and supplies a gas for forming a gate insulating film. A gas supply unit 408i is connected to the second reaction chamber 400b and supplies a gas for forming a microcrystalline germanium film. A gas supply unit 408b is connected to the third reaction chamber 400c and supplies a gas for forming a buffer layer. A gas supply unit 408n is connected to the fourth reaction chamber 400d and supplies a gas for forming an n-type semiconductor film, for example. In addition, phosphine which is one of gases including an impurity element which serves as a donor may also be supplied to the first reaction chamber 400a and the second reaction chamber 400b. A gas supply unit 408a supplies argon, and a gas supply unit 408f supplies an etching gas used for cleaning of the inside of the reaction chambers. Thus, the gas supply units 408a and 408f are provided in common for each reaction chamber.

A high-frequency power supply unit for generating plasma is connected to each reaction chamber. The high-frequency power supply unit includes a high-frequency power source 404 and a matching box 406.

Each reaction chamber can be used for a different purpose, depending on the kinds of thin films to be formed. Since each thin film has an optimum temperature for being formed, by forming each thin film in a different reaction chamber, film formation temperatures can be easily controlled. Further, the same kind of films can be repeatedly formed, so that an influence of a residual impurity due to a film which has been formed can be eliminated. In particular, when the microcrystalline germanium film includes an impurity element which serves as a donor, the impurity element which serves as a donor can be prevented from being mixed into the buffer layer. Consequently, the concentration of the impurity element in the buffer layer can be reduced, whereby off-current of the thin film transistor can be reduced.

A microcrystalline germanium film, a buffer layer, and a semiconductor film to which an impurity element imparting one conductivity type is added may be formed successively in one reaction chamber. Specifically, a substrate provided with a gate insulating film is carried into a reaction chamber, and a microcrystalline germanium film, a buffer layer, and a semiconductor film to which an impurity element imparting one conductivity type is added are formed therein successively. Then, after the substrate is taken out of the reaction chamber, the inside of the reaction chamber is preferably cleaned with fluorine radicals.

This embodiment mode describes an inverted staggered thin film transistor as a thin film transistor, but the present invention is not limited thereto and can be applied to a staggered thin film transistor, a top gate thin film transistor, and the like. Specifically, a microcrystalline germanium film may be formed over an insulating film functioning as a base film, and a gate insulating film and a gate electrode may be formed over the microcrystalline germanium film, so that a thin film transistor having the microcrystalline germanium film can be manufactured.

In accordance with this embodiment mode, an inverted staggered thin film transistor with excellent electric characteristics and an element substrate provided with the inverted staggered thin film transistor can be manufactured.

### Embodiment Mode 5

In this embodiment mode, a method for manufacturing a thin film transistor including a microcrystalline germanium film which has high crystallinity at the interface with a gate insulating film will be described.

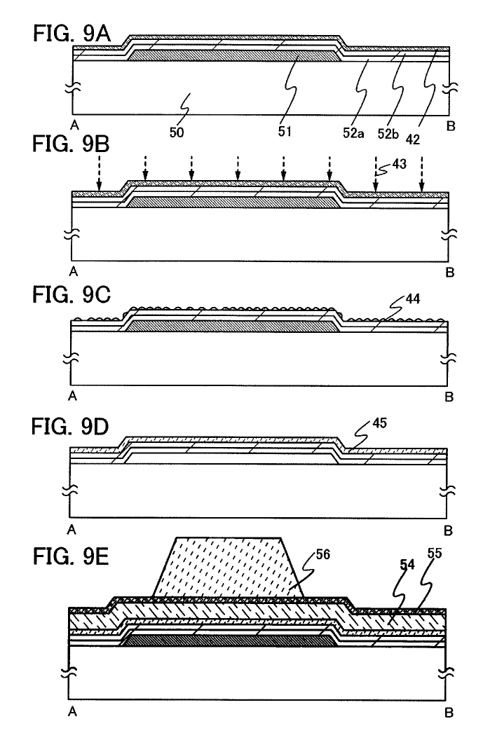

As in Embodiment Mode 4, as illustrated in FIG. 9A, a gate electrode 51 is formed over a substrate 50, gate insulating films 52a and 52b are formed over the gate electrode 51, and a germanium film 42 is formed over the gate insulating film 52b.

As the germanium film 42, an amorphous germanium film or a microcrystalline germanium film is formed. As a microcrystalline germanium film, a microcrystalline germanium film including crystal grains with a diameter of 0.5 to 100 nm, preferably 1 to 20 nm can be used. Note that, in the case where the germanium film 42 is a microcrystalline germanium film, the microcrystalline germanium film may include amorphous components. The thickness of the germanium film 42 is 1 to 100 nm, preferably 2 to 20 nm, more preferably 5 to 10 nm.

The germanium film 42 can be formed by a sputtering method or a CVD method. In the case where the germanium film 42 is formed by a sputtering method, sputtering is performed on a germanium target using hydrogen or a rare gas, whereby an amorphous germanium film is formed over the gate insulating film 52b as the germanium film 42. In the case where the germanium film 42 is formed by a CVD method, hydrogen is introduced to a reaction chamber of a plasma CVD apparatus in addition to a deposition gas including germanium, and high-frequency power is applied, whereby plasma is generated, so that an amorphous germanium film or a microcrystalline germanium film is formed over the gate insulating film 52b as the germanium film 42.

In one mode for forming an amorphous germanium film as the germanium film 42, an amorphous germanium film can be formed by glow discharge plasma using a deposition gas including germanium in the reaction chamber. Alternatively, a deposition gas including germanium is diluted with one or plural kinds of rare gas elements selected from helium, argon, krypton, or neon, and an amorphous germanium film can be formed by glow discharge plasma. Further alternatively, an amorphous germanium film can be formed by glow discharge plasma using hydrogen with a flow rate of 1 to 10 times, preferably 1 to 5 times as high as that of a deposition gas including germanium.

In addition, in one mode for forming a microcrystalline germanium film as the germanium film 42, a deposition gas including germanium, which is germane here, and hydrogen, and/or a rare gas are mixed in the reaction chamber, and the microcrystalline germanium film is formed by glow discharge plasma. Germane is diluted with hydrogen and/or a rare gas to be 10 to 2000 times thinner. Thus, a large amount of hydrogen and/or a rare gas is necessary. The substrate heating temperature is 100 to 400° C., preferably 250 to 350° C.

In a process for forming the germanium film 42, glow discharge plasma is generated by applying high-frequency power with a frequency of 1 to 30 MHz, typically 13.56 MHz or 27.12 Mz, or high-frequency power with a frequency in the VHF band of 30 to about 300 MHz, typically 60 MHz.

Next, as illustrated in FIG. 9B, the germanium film 42 is exposed to plasma 43 so as to form crystal nuclei 44 illustrated in FIG. 9C. As for the plasma 43, at least one of hydrogen, fluorine, and a fluoride is introduced to the reaction chamber of the plasma CVD apparatus, and high-frequency power is applied, whereby plasma is generated.

At least one of fluorine, a fluoride gas, and hydrogen is introduced, and high-frequency power is applied, whereby hydrogen plasma or fluorine plasma is generated. The hydrogen plasma is generated by introducing hydrogen to the reaction chamber. The fluorine plasma is generated by introducing fluorine or a fluoride to the reaction chamber. As examples of a fluoride, HF, GeF₄, GeHF₃, GeH₂F₂, GeH₃F, Ge₂F₆, and the like are given. Note that, in addition to fluorine, a fluoride gas, or hydrogen, a rare gas may be introduced to the reaction chamber so that rare gas plasma is generated.

Hydrogen radicals or fluorine radicals are generated in plasma by hydrogen plasma, fluorine plasma, or the like. The hydrogen radicals react with an amorphous germanium film to crystallize a part of the amorphous germanium film and to etch amorphous components. The fluorine radicals etch amorphous components of a germanium film. Accordingly, in the case where the germanium film 42 is a microcrystalline germanium film, since crystal grains included in the film are small, crystal nuclei having high crystallinity can be left at high density by etching amorphous components which fill spaces between the crystal grains. In the case where the germanium film 42 formed over the gate insulating film 52b is an amorphous germanium film, amorphous components are etched and partly crystallized so that fine crystal nuclei can be formed. Thus, amorphous components at the interface with the gate insulating film are also etched with plasma. Accordingly, crystal nuclei having high crystallinity can be formed over the gate insulating film.

As a method for generating plasma, the HF band (3 to 30 MHz, typically 13.56 MHz) is preferably used. In particular, by using high-frequency power with a frequency of 13.56 MHz, uniformity of plasma can be increased. Thus, the germanium film can be exposed to plasma with high uniformity even over a large-sized substrate, i.e., the sixth to tenth generation substrates, which is preferable for mass production.

As one mode, here, hydrogen and/or a rare gas are/is introduced to the reaction chamber of the plasma CVD apparatus, to generate hydrogen plasma with glow discharge plasma. The germanium film 42 is exposed to the hydrogen plasma and amorphous germanium components of the germanium film 42 are etched, so that crystal nuclei 44 are formed.

Next, crystals are grown using the crystal nuclei 44, whereby a microcrystalline germanium film 45 is formed (FIG. 9D). In this mode, in the reaction chamber of the plasma CVD apparatus, a deposition gas including germanium, here, germane, and hydrogen, and/or a rare gas are mixed, to form the microcrystalline germanium film by glow discharge plasma. Germane is diluted with hydrogen and/or a rare gas to be 10 to 2000 times thinner. The substrate heating temperature is 100 to 400° C., preferably 250 to 350° C. Crystals are grown in a normal direction with respect to the surface of the gate insulating film 52b from the crystal nuclei over the gate insulating film 52b, whereby a microcrystalline germanium film including columnar-like crystal grains can be formed. In addition, the microcrystalline germanium film can have high crystallinity at the interface with the gate insulating film 52b and also in the film itself.

In addition to a deposition gas including germanium, a fluoride gas including germanium is used in order to form the microcrystalline germanium film. Thus, amorphous germanium components in a region where crystals grow are etched with fluorine radicals when crystals grow from crystal nuclei. Accordingly, crystal growth providing high crystallinity can be achieved, that is, a microcrystalline germanium film having high crystallinity can be formed. The flow rate of germane fluoride is set to be 0.1 to 50 times, preferably 1 to 10 times that of germane, and the flow rate of hydrogen is set to be 10 to 2000 times, preferably 50 to 200 times that of germane for dilution, whereby the microcrystalline germanium film is formed.

Through the above process, the microcrystalline semiconductor film 45 which has high crystallinity at the interface with the gate insulating film 52b can be formed.

Next, as illustrated in FIG. 9E, a buffer layer 54 and a semiconductor film 55 to which an impurity element imparting one conductivity type is added are formed in order over the microcrystalline germanium film 45. Then, a resist mask 56 is formed over the semiconductor film 55 to which the impurity element imparting one conductivity type is added.

After that, through the process similar to that in Embodiment Mode 4, a thin film transistor as illustrated in Embodiment Mode 1 can be manufactured.

This embodiment mode describes an inverted staggered thin film transistor as a thin film transistor, but the present invention is not limited thereto and can be applied to a staggered thin film transistor, a top gate thin film transistor, and the like. Specifically, a microcrystalline germanium film may be formed over an insulating film functioning as a base film, and a gate insulating film and a gate electrode may be formed over the microcrystalline germanium film, so that a thin film transistor including a microcrystalline germanium film having high crystallinity at the interface with the insulating film functioning as a base film can be manufactured.

### Embodiment Mode 6

In this embodiment mode, similarly to Embodiment Mode 5, a method for manufacturing a thin film transistor including a microcrystalline germanium film which has high crystallinity at the interface with a gate insulating film will be described.

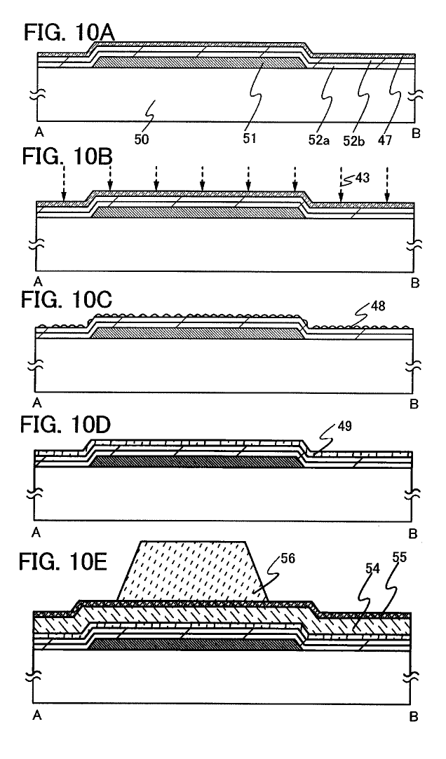

As in Embodiment Mode 4, as illustrated in FIG. 10A, a gate electrode 51 is formed over a substrate 50, gate insulating films 52a and 52b are formed over the gate electrode 51, and a germanium film 47 is formed over the gate insulating film 52b.

In this embodiment mode, as the germanium film 47, a germanium film including an impurity element which serves as a donor is formed. The germanium film including the impurity element which serves as a donor is formed by a plasma CVD method or a sputtering method. As the impurity element which serves as a donor, phosphorus, arsenic, or antimony is used. Further, as the germanium film, an amorphous germanium film or a microcrystalline germanium film is formed.

The germanium film 47 including the impurity element which serves as a donor may be formed using a gas including the impurity element which serves as a donor in addition to the source gas for the germanium film 42 described in Embodiment Mode 5. For example, an amorphous germanium film or a microcrystalline germanium film including phosphorus can be formed by a plasma CVD method using phosphine in addition to germane and hydrogen.

The concentration of the impurity element which serves as a donor is 6×10¹⁵ to 3×10¹⁸ atoms/cm³ inclusive, preferably 1×10¹⁶ to 3×10¹⁸ atoms/cm³ inclusive, more preferably 3×10¹⁶ to 3×10¹⁷ atoms/cm³ inclusive. The concentration of the impurity element which serves as a donor is set to be in the above range, whereby the interface between the gate insulating film 52b and a later-formed microcrystalline germanium film including the impurity element which serves as a donor can have improved crystallinity.

Alternatively, before formation of the germanium film 47, a gas including the impurity element which serves as a donor may be supplied into a reaction chamber of a film formation apparatus, and the impurity element which serves as a donor may be adsorbed onto the surface of the gate insulating film 52b and the inner wall of the reaction chamber. After that, the germanium film may be deposited. Accordingly, because the germanium film can be deposited while taking in the impurity element which serves as a donor, the germanium film 47 including the impurity element which serves as a donor can be formed.

Next, crystal nuclei whose crystallinity is high are formed using the germanium film 47. As illustrated in FIG. 10B, the germanium film 47 including the impurity element which serves as a donor is irradiated with plasma 43. As a result, as illustrated in FIG. 1C, crystal nuclei 48 including the impurity element which serves as a donor are formed over the gate insulating film 52b. As the plasma 43, the plasma 43 described in Embodiment Mode 5 can be used as appropriate.

Further, instead of the germanium film 47 including the impurity element which serves as a donor, the germanium film 42 described in Embodiment Mode 5 may be formed, and in order to generate the plasma 43, a gas including the impurity element which serves as a donor may be introduced to the reaction chamber in addition to hydrogen, fluorine, or a fluoride. Amorphous components of the germanium film are etched with hydrogen, fluorine, or a fluoride, and the impurity element which serves as a donor may be added to the germanium film which is left, whereby the crystal nuclei 48 including the impurity element which serves as a donor can be formed.

Then, a deposition gas including germanium, and hydrogen are introduced to the reaction chamber, and high-frequency power is applied, whereby crystals are grown using the crystal nuclei 48, and a microcrystalline germanium film 49 including the impurity element which serves as a donor is formed as illustrated in FIG. 10D. Alternatively, the microcrystalline germanium film may be formed using a fluoride gas including germanium in addition to a deposition gas including germanium. Here, germane and hydrogen, and/or a rare gas are mixed, to form the microcrystalline germanium film including the impurity element which serves as a donor by glow discharge plasma.

Before formation of the microcrystalline germanium film 49, an amorphous germanium film or a microcrystalline germanium film is preferably formed on the inner wall of the reaction chamber of the film formation apparatus. It is preferable that the inner wall of the reaction chamber be cleaned with fluorine plasma or the like, and then, an amorphous germanium film or a microcrystalline germanium film be formed on the inner wall of the reaction chamber. By such treatment, when the germanium film 47 or the microcrystalline germanium film 49 is formed, mixture of a material of the inner wall of the reaction chamber or fluorine used for the cleaning into the germanium film 47 or the microcrystalline germanium film 49 can be reduced.

Further, the impurity element which serves as a donor may be added to the amorphous germanium film or the microcrystalline germanium film formed on the inner wall of the reaction chamber. The concentration of the impurity element which serves as a donor is 6×10¹⁵ to 3×10¹⁸ atoms/cm³ inclusive, preferably 1×10¹⁶ to 3×10¹⁸ atoms/cm³ inclusive, more preferably 3×10¹⁶ to 3×10¹⁷ atoms/cm³ inclusive. By such treatment, when the reaction chamber is vacuum-evacuated, the impurity element which serves as a donor and is attached to the inner wall of the reaction chamber is released in the reaction chamber. The released impurity element which serves as a donor is mixed into the germanium film 47, and thus, the germanium film 47 including the impurity element which serves as a donor can be formed.

Instead of forming the germanium film 47 including the impurity element which serves as a donor, a germanium film which does not include the impurity element which serves as a donor may be formed, and an insulating film including the impurity element which serves as a donor may be formed as the gate insulating film 52b. For example, a silicon oxide film, a silicon nitride film, a silicon oxynitride film, a silicon nitride oxide film, or the like including the impurity element which serves as a donor (phosphorus, arsenic, or antimony) can be used. In the case of employing a stacked-layer structure for the gate insulating film 52b, the impurity element which serves as a donor may be added to a layer in contact with the germanium film 47 or a layer in contact with the gate insulating film 52a.

In a method for forming the insulating film including the impurity element which serves as a donor as the gate insulating film 52b, the insulating film may be formed using a gas including the impurity element which serves as a donor in addition to a source gas of the insulating film. For example, a silicon nitride film including phosphorus can be formed by a plasma CVD method using silane, ammonia, and phosphine. Further, a silicon oxynitride film including phosphorus can be formed by a plasma CVD method using silane, dinitrogen monoxide, ammonia, and phosphine.

Before formation of the gate insulating film 52b, a gas including the impurity element which serves as a donor may be supplied into the reaction chamber of the film formation apparatus, and the impurity element which serves as a donor may be adsorbed onto the surface of the gate insulating film 52a and the inner wall of the reaction chamber. After that, the gate insulating film 52b may be formed, and then, the germanium film 47 may be formed. Accordingly, because the gate insulating film 52b and the germanium film 47 can be deposited while taking in the impurity element which serves as a donor, the germanium film 47 including the impurity element which serves as a donor can be formed.

Further, as the microcrystalline germanium film 49, a microcrystalline germanium film including the impurity element which serves as a donor may be formed. As for a method for forming the microcrystalline germanium film including the impurity element which serves as a donor, a gas including the impurity element which serves as a donor may be used, in addition to the source gas of the microcrystalline germanium film. For example, a microcrystalline germanium film including phosphorus can be formed by a plasma CVD method using germane, hydrogen, and phosphine.

Alternatively, before formation of the microcrystalline germanium film 49, a gas including the impurity element which serves as a donor may be supplied into the reaction chamber of the film formation apparatus, and the impurity element which serves as a donor may be adsorbed onto the surfaces of the gate insulating film 52b and the crystal nuclei 48 and the inner wall of the reaction chamber. After that, the microcrystalline germanium film 49 may be deposited. Accordingly, because the microcrystalline germanium film can be deposited while taking in the impurity element which serves as a donor, the microcrystalline germanium film 49 including the impurity element which serves as a donor can be formed.

Further, the impurity element which serves as a donor may be added to two or more of the gate insulating film 52b, the germanium film 47, the crystal nuclei 48, and the microcrystalline germanium film 49.

Through the above process, a microcrystalline germanium film which has high crystallinity at the interface with a gate insulating film and also in the film itself can be formed.

Next, as illustrated in FIG. 10E, a buffer layer 54 and a semiconductor film 55 to which an impurity element imparting one conductivity type is added are formed in order over the microcrystalline germanium film 49 including the impurity element which serves as a donor. Then, a resist mask 56 is formed over the semiconductor film 55 to which the impurity element imparting one conductivity type is added.

After that, through the process similar to that in Embodiment Mode 4, a thin film transistor as described in Embodiment Mode 2 can be manufactured.

This embodiment mode describes an inverted staggered thin film transistor as a thin film transistor, but the present invention is not limited thereto and can be applied to a staggered thin film transistor, a top gate thin film transistor, and the like. Specifically, a microcrystalline germanium film may be formed over an insulating film functioning as a base film, and a gate insulating film and a gate electrode may be formed over the microcrystalline germanium film, so that a thin film transistor including a microcrystalline germanium film having high crystallinity at the interface with the insulating film functioning as a base film can be manufactured.

### Embodiment Mode 7

In this embodiment mode, similarly to Embodiment Mode 5, a method for manufacturing a thin film transistor including a microcrystalline germanium film which has high crystallinity at the interface with a gate insulating film will be described.

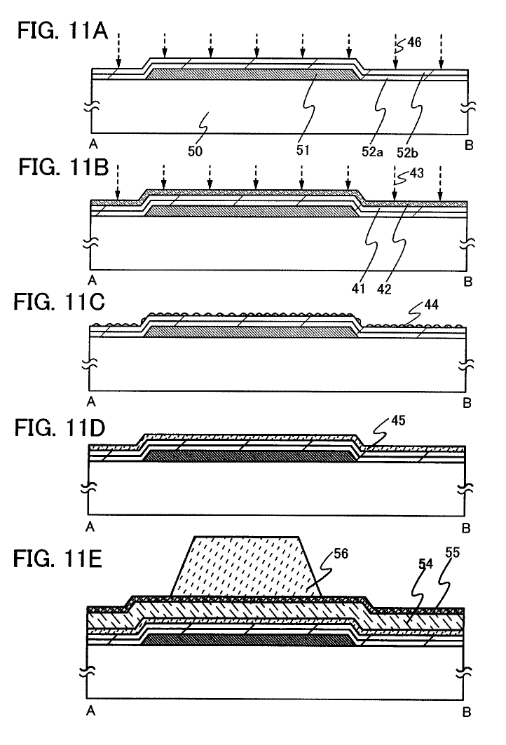

As in Embodiment Mode 4, as illustrated in FIG. 11A, a gate electrode 51 is formed over a substrate 50, and gate insulating films 52a and 52b are formed over the gate electrode 51.

Next, the surface of the gate insulating film 52b is exposed to plasma 46, whereby a gate insulating film 41 having an uneven surface with projections and depressions is formed as illustrated in the enlarged view 40 of FIG. 3 and FIG. 11B. Each of the projections and depressions may have a wavelike shape with a gentle curve to form the uneven shape. Alternatively, the projections may have a sharp needle-like shape and the depressions may have a gently curved shape. With small spaces between the projections and depressions, crystal nuclei can be formed at high density later, which is preferable.

The gate insulating film 52b is exposed to the plasma 46 which makes the surface of the gate insulating film 52b uneven. Such plasma 46 is generated by introducing at least one of fluorine, a fluoride gas, and hydrogen into a reaction chamber and applying high-frequency power. By being exposed to the plasma 46, the surface of the gate insulating film 52b is etched, whereby the uneven gate insulating film 41 is formed.

Next, a germanium film 42 is formed over the gate insulating film 41. Since the surface of the gate insulating film 41 is uneven, the germanium film 42 also has an uneven surface where the height difference between the top of the projection and the bottom of the depression is several nm to several tens of nm, although not illustrated. Then, as in Embodiment Mode 5, crystal nuclei with high crystallinity are formed at high density. Here, also, plasma 43 is generated by introducing at least one of fluorine, a fluoride gas, and hydrogen into the reaction chamber of a plasma CVD apparatus and applying high-frequency power, and the germanium film 42 is exposed to the plasma 43, whereby a part of the germanium film 42, typically, an amorphous component thereof is etched. In this embodiment mode, since the surface of the germanium film 42 is uneven, crystal nuclei can more easily be formed owing to stress concentration at the germanium film 42.

As a result, crystal nuclei 44 with high crystallinity can be formed as illustrated in FIG. 11C.

Then, a deposition gas including germanium, and hydrogen are introduced to the reaction chamber, and high-frequency power is applied, whereby crystals are grown using the crystal nuclei 44 and a microcrystalline germanium film 45 is formed as illustrated in FIG. 11D. Here, germane and hydrogen, and/or a rare gas are mixed to form the microcrystalline germanium film by glow discharge plasma.

Through the above process, a microcrystalline germanium film which has high crystallinity at the interface with an insulating film and also in the film itself can be formed.

Next, as illustrated in FIG. 11E, a buffer layer 54 and a semiconductor film 55 to which an impurity element imparting one conductivity type is added are formed in order over the microcrystalline germanium film 45. Then, a resist mask 56 is formed over the semiconductor film 55 to which the impurity element imparting one conductivity type is added.

After that, through a process similar to Embodiment Mode 4, a thin film transistor as described in Embodiment Mode 3 can be manufactured.

This embodiment mode describes an inverted staggered thin film transistor as a thin film transistor, but the present invention is not limited thereto and can be applied to a staggered thin film transistor, a top gate thin film transistor, and the like. Specifically, a microcrystalline germanium film may be formed over an insulating film functioning as a base film, and a gate insulating film and a gate electrode may be formed over the microcrystalline germanium film, so that a thin film transistor including a microcrystalline germanium film having high crystallinity at the interface with the insulating film functioning as a base film can be manufactured.

### Embodiment Mode 8

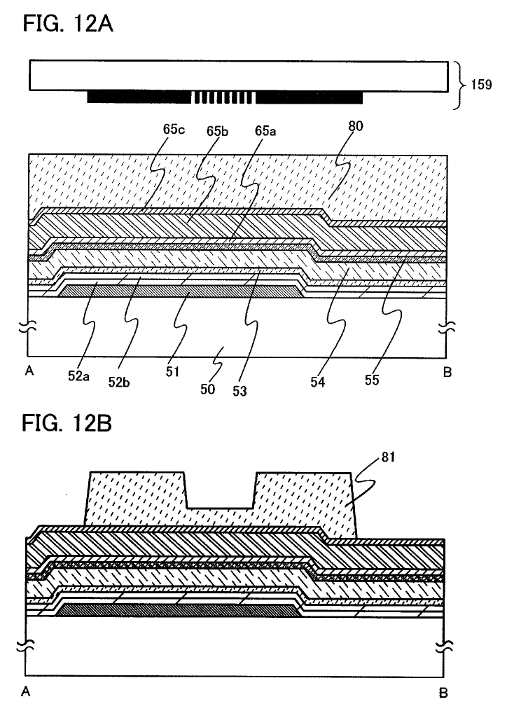

Next, a method for manufacturing a thin film transistor, which is different from those in the above embodiment modes, will be described with reference to FIGS. 12A and 12B, FIGS. 13A to 13D, FIGS. 14A to 14C, FIGS. 15A and 15B, FIGS. 16A and 16B, FIGS. 17A to 17C, and FIGS. 18A to 18C. Here, a process is described through which the number of photomasks can be smaller than that of the above embodiment modes and through which a thin film transistor can be manufactured.

In a similar manner to Embodiment Mode 4, a conductive film is formed over a substrate 50, a resist is applied on the conductive film, and a part of the conductive film is etched using a resist mask which is formed by a photolithography process using a first photomask, so that a gate electrode 51 is formed. Then, as illustrated in FIG. 12A, gate insulating films 52a and 52b are formed over the gate electrode 51. Next, a microcrystalline germanium film 53, a buffer layer 54, a semiconductor film 55 to which an impurity element imparting one conductivity type is added, and conductive films 65a to 65c are formed in order. Then, a resist 80 is applied on the conductive film 65c. Any of Embodiment Modes 5 to 7 can be applied as appropriate, in order to form the microcrystalline germanium film.

The resist 80 can be a positive type resist or a negative type resist. In this case, a positive type resist is used.

Next, a multi-tone mask 159 is used as a second photomask and the resist 80 is irradiated with light, whereby the resist 80 is exposed to light.

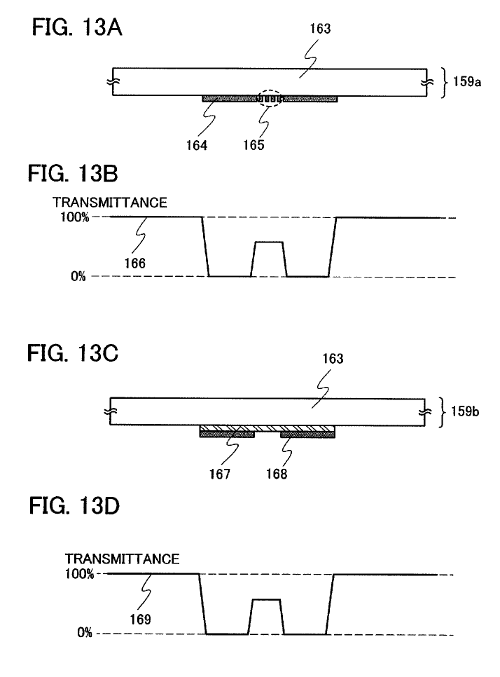

Now, light exposure using the multi-tone mask 159 is described with reference to FIGS. 13A to 13D.

A multi-tone mask can achieve three levels of light exposure, an exposed portion, a half-exposed portion, and an unexposed portion; one-time light exposure and development process allows a resist mask with regions of plural thicknesses (typically, two kinds of thicknesses) to be formed. Thus, the use of the multi-tone mask can reduce the number of photomasks.

Typical examples of the multi-tone mask include a gray-tone mask 159a illustrated in FIG. 13A and a half-tone mask 159b illustrated in FIG. 13C.

As illustrated in FIG. 13A, the gray-tone mask 159a includes a light-transmitting substrate 163 provided with a light-blocking portion 164 and a diffraction grating 165. The light transmittance of the light-blocking portion 164 is 0%. The diffraction grating 165 has a light-transmitting portion in a slit form, a dot form, a mesh form, or the like with intervals which are less than or equal to the resolution limit of light used for the exposure; thus, the light transmittance can be controlled. The diffraction grating 165 can be in a slit form, a dot form, or a mesh form with regular intervals; or in a slit form, a dot form, or a mesh form with irregular intervals.

For the light-transmitting substrate 163, a substrate having a light-transmitting property, such as a quartz substrate, can be used. The light-blocking portion 164 and the diffraction grating 165 can be formed using a light-blocking material such as chromium or chromium oxide, which absorbs light.

When the gray-tone mask 159a is irradiated with light for exposure, a light transmittance 166 of the light-blocking portion 164 is 0% and that of a region where neither the light-blocking portion 164 nor the diffraction grating 165 is provided is 100%, as illustrated in FIG. 13B. The light transmittance of the diffraction grating 165 can be controlled in a range of 10 to 70%. The light transmittance of the diffraction grating 165 can be controlled with the adjustment of an interval or a pitch of slits, dots, or meshes of the diffraction grating 165.

As illustrated in FIG. 13C, the half-tone mask 159b includes a light-transmitting substrate 163 provided with a semi-light-transmitting portion 167 and a light-blocking portion 168. MoSiN, MoSi, MoSiO, MoSiON, CrSi, or the like can be used for the semi-light-transmitting portion 167. The light-blocking portion 168 can be formed using a light-blocking material such as chromium or chromium oxide, which absorbs light.

When the half-tone mask 159b is irradiated with light for exposure, a light transmittance 169 of the light-blocking portion 168 is 0% and that of a region where neither the light-blocking portion 168 nor the semi-light-transmitting portion 167 is provided is 100%, as illustrated in FIG. 13D. The light transmittance of the semi-light-transmitting portion 167 can be controlled in a range of 10 to 70%. The light transmittance of the semi-light-transmitting portion 167 can be controlled with the material of the semi-light-transmitting portion 167.

After the light exposure using the multi-tone mask is performed, development is carried out, whereby a resist mask 81 having regions with different thicknesses can be formed, as illustrated in FIG. 12B.

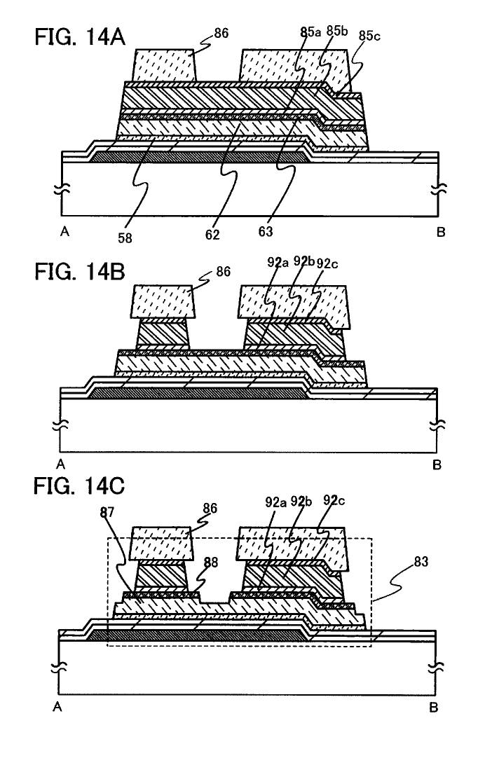

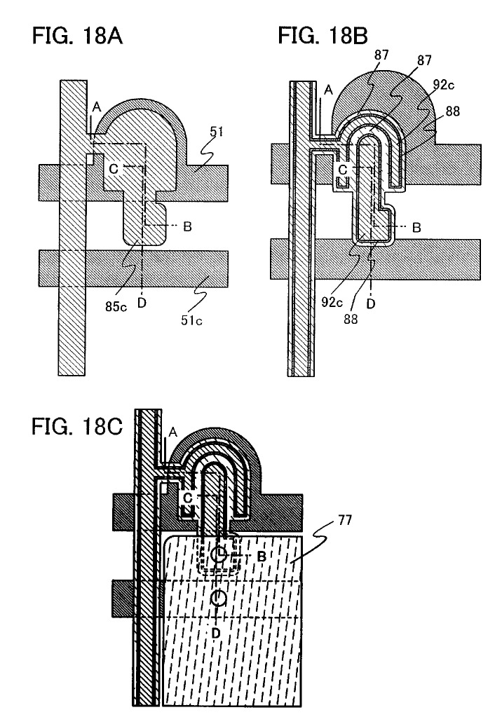

Next, with the resist mask 81, the microcrystalline germanium film 53, the buffer layer 54, the semiconductor film 55 to which the impurity element imparting one conductivity type is added, and the conductive films 65a to 65c are etched. As a result, a microcrystalline germanium film 58, a buffer layer 62, a semiconductor film 63 to which the impurity element imparting one conductivity type is added, and conductive films 85a to 85c can be formed, as illustrated in FIG. 14A. FIG. 14A illustrates a cross section taken along a line A-B of FIG. 18A (except for the resist mask 81).

Next, ashing is conducted on the resist mask 81. As a result, the area and the thickness of the resist are reduced. At this time, the resist in a region with a small thickness (a region overlapping with a part of the gate electrode 51) is removed to form a separated resist mask 86, as illustrated in FIG. 14A.

Next, the conductive films 85a to 85c are etched to be separated using the resist mask 86. As a result, pairs of wirings 92a to 92c can be formed as illustrated in FIG. 14B. Here, the conductive films 85a to 85c are etched by wet etching using the resist mask 86, so that the conductive films 85a to 85c are isotropically etched. Consequently, the wirings 92a to 92c, which have smaller areas than the resist mask 86, can be formed.

Next, the semiconductor film 63 to which the impurity element imparting one conductivity type is added is etched using the resist mask 86, so that a pair of a source and drain regions 88 are formed. Note that, in this etching step, a part of the buffer layer 62 is also etched. The buffer layer which is partly etched is referred to as a buffer layer 87. The buffer layer 87 has a recessed portion. The source and drain regions and the recessed portion of the buffer layer can be formed in the same process. Here, the buffer layer 62 is partly etched with the use of the resist mask 86 having a smaller area than the resist mask 81, so that end portions of the buffer layer 87 are located outside those of the source and drain regions 88. In addition, the end portions of the wirings 92a to 92c are not aligned with those of the source and drain regions 88, and the end portions of the source and drain regions 88 are formed outside those of the wirings 92a to 92c. After that, the resist mask 86 is removed.

Next, dry etching may be performed under such a condition that the buffer layer which is exposed is not damaged and an etching rate with respect to the buffer layer is low. Through this dry etching step, an etching residue on the buffer layer between the source region and the drain region, a residue of the resist mask, and a contamination source in the apparatus used for removal of the resist mask can be removed, whereby the source region and the drain region can be certainly insulated. As a result, leak current of the thin film transistor can be reduced, so that a thin film transistor with small off-current and high withstand voltage can be manufactured. A gas including chlorine, a gas including fluorine, or the like can be used for an etching gas, for example.

As illustrated in FIG. 14C, the end portions of the wirings 92a to 92c are not aligned with those of the source and drain regions 88, and the end portions of the wirings 92a to 92c can have a larger distance therebetween; thus, leak current or short-circuit between the wirings can be prevented. In this manner, an inverted staggered thin film transistor can be manufactured.

Through the above-described process, a channel-etched thin film transistor 83 can be formed. In addition, the thin film transistor can be formed using two photomasks.

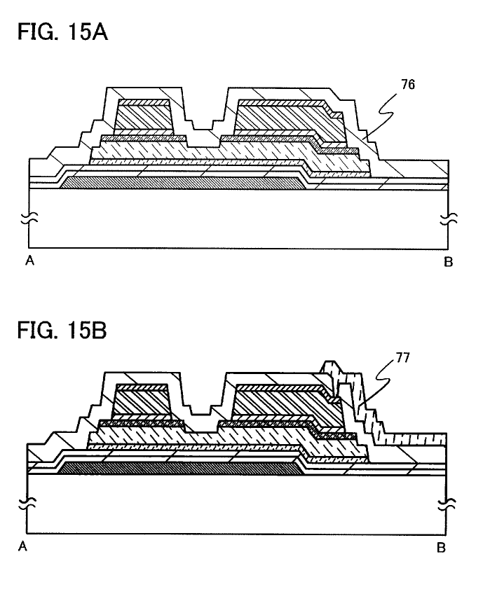

Next, as illustrated in FIG. 15A, a protective insulating film 76 is formed over the wirings 92a to 92c, the source and drain regions 88, the buffer layer 87, the microcrystalline germanium film 58, and the gate insulating film 52b.

Next, a part of the protective insulating film 76 is etched using a resist mask formed using a third photomask, so that a contact hole is formed. Next, a pixel electrode 77 in contact with the wiring 92c in the contact hole is formed. In this example, in order to form the pixel electrode 77, an ITO film is formed by a sputtering method, and then, a resist is applied on the ITO film. Then, the resist is exposed to light and developed using a fourth photomask, thereby forming a resist mask, and then, the ITO film is etched using the resist mask to form the pixel electrode 77. FIG. 15B illustrates a cross section taken along a line A-B in FIG. 18C.

Through the above process, a thin film transistor and an element substrate which includes the thin film transistor and can be used for a display device can be formed.

Next, a process capable of forming a contact hole and a capacitor element with one photomask will be described. Cross-sectional views taken along lines C-D in FIGS. 18A to 18C are used here.

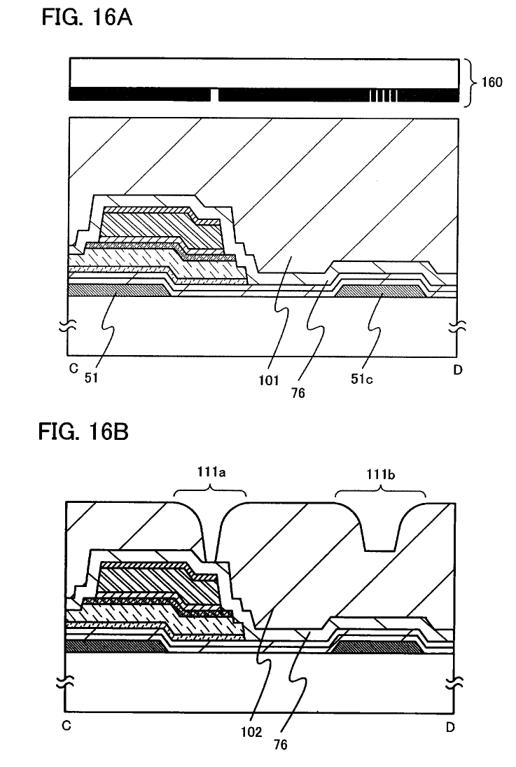

After the step illustrated in FIG. 15A, an insulating film 101 is formed over the protective insulating film 76 as illustrated in FIG. 16A. The insulating film 101 is formed using a photosensitive organic resin here. Then, the insulating film 101 is exposed to light using a multi-tone mask 160 and developed, whereby a recessed portion 111a which exposes the protective insulating film 76 covering the wiring of the thin film transistor and a recessed portion 111b over a capacitor wiring 51c are formed as illustrated in FIG. 16B. Here, by use of the multi-tone mask 160, the insulating film 101 over the wiring of the thin film transistor can be exposed to light at 100%, and the insulating film 101 over the capacitor wiring 51c can be exposed to light at 10 to 70%.

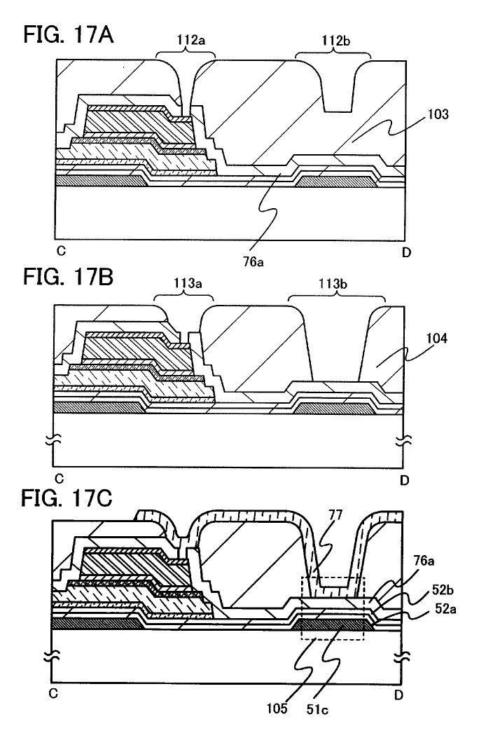

Next, an insulating film 102 having the recessed portions is etched (etch back), and then a part of the protective insulating film 76 is etched. As a result, an insulating film 103 having a contact hole 112a which exposes the wiring and a recessed portion 112b over the capacitor wiring 51c is formed as illustrated in FIG. 17A.

Next, ashing is conducted on the insulating film 103, and the areas of the contact hole 112a and the recessed portion 112b are widened, so that an insulating film 104 having a contact hole 113a and a recessed portion 113b is formed. Since the protective insulating film 76 is not formed of a photosensitive organic resin but formed of an inorganic insulating film, it is not processed by ashing. Therefore, the contact hole 113a over the wiring has a top shape with double circles.

After that, a pixel electrode 77 is formed, and a capacitor element 105 including the capacitor wiring 51c, the gate insulating films 52a and 52b, a protective insulating film 76a, and the pixel electrode 77 can be formed.

Through the above process, the contact hole connecting the pixel electrode and the wiring, and the capacitor element can be formed by using only one multi-tone mask.

### Embodiment Mode 9

In this embodiment mode, a structure of a thin film transistor which can be applied to Embodiment Modes 1 to 8 will be described.

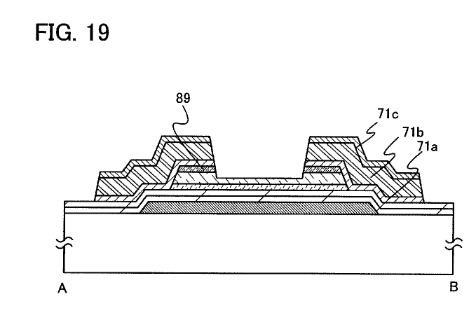

After forming the wirings 71a to 71c of Embodiment Mode 4 illustrated in FIG. 5B or the wirings 92a to 92c of Embodiment Mode 8 illustrated in FIG. 14B, the resist mask 66 or 86 may be removed, and the semiconductor film 63 to which the impurity element imparting one conductivity type is added may be etched using the wirings 71a to 71c or 92a to 92c as masks. As a result, a thin film transistor in which end portions of the wirings 71a to 71c or 92a to 92c are aligned with those of the semiconductor films 72 or 88 functioning as a source and drain regions can be formed. Here, after removing the resist mask 66 illustrated in FIG. 5B, the semiconductor film 63 to which the impurity element imparting one conductivity type is added is etched using the wirings 71a to 71c as masks, so that a thin film transistor in which end portions of semiconductor films 89 functioning as a source and drain regions are aligned with those of the wirings 71a to 71c can be formed as illustrated in FIG. 19.

Although Embodiment Modes 1 to 8 describe channel-etched thin film transistors, each of the thin film transistors described in Embodiment Modes 1 to 8 can also be a channel protective thin film transistor.

Specifically, as illustrated in FIG. 4A, a gate electrode 51 is formed over a substrate 50, and gate insulating films 52a and 52 are formed over the gate electrode 51. Then, a microcrystalline germanium film 53 is formed thereover.

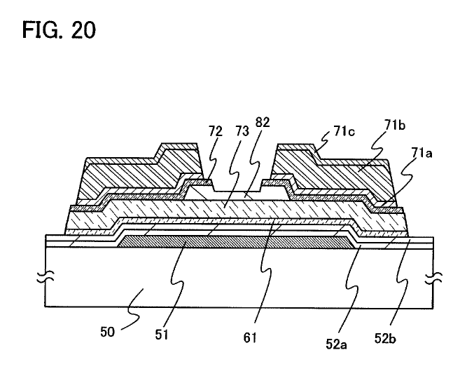

As illustrated in FIG. 4B, a buffer layer 54 is formed over the microcrystalline germanium film 53. Then, a channel protective film is formed in a region which is over the buffer layer 54 and which overlaps with the gate electrode 51. The channel protective film is formed by forming a silicon nitride film, a silicon oxide film, a silicon nitride oxide film, or a silicon oxynitride film and selectively etching the film through a photolithography process. Alternatively, the channel protective film can be formed by discharging a composition including polyimide, acrylic, or siloxane and baking it. Next, a semiconductor film to which an impurity element imparting one conductivity type is added and conductive films are formed in this order. Then, using a resist mask which is formed through a photolithography process, the conductive films, the semiconductor film to which the impurity element imparting one conductivity type is added, the buffer layer, and the microcrystalline germanium film are etched. Consequently, a microcrystalline germanium film 61, a buffer layer 73, semiconductor films 72 which function as a source and drain regions, and wirings 71a to 71c which function as a source and drain electrodes are formed as illustrated in FIG. 20. Further, a channel protective film 82 having a recessed portion in a part thereof is formed.

Through the above process, a channel protective thin transistor can be formed.

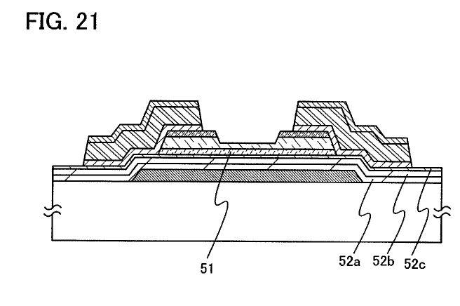

Instead of the gate insulating films 52a and 52b of the thin film transistor described in Embodiment Modes 1 to 8, three gate insulating films 52a, 52b, and 52c may be formed as illustrated in FIG. 21. As the gate insulating film 52c, which is a third layer, a silicon nitride film or a silicon nitride oxide film with a thickness of 1 to 5 nm approximately can be formed.

The silicon nitride film or the silicon nitride oxide film with a thickness of 1 to 5 nm approximately, which is the third gate insulating film 52c, can be formed by a plasma CVD method. Further, it is also possible to have the gate insulating film 52b undergo nitridation treatment with high-density plasma to form a silicon nitride layer over the surface of the gate insulating film 52b. By high-density plasma nitridation, a silicon nitride layer that includes nitrogen at a higher concentration can be obtained. The high-density plasma is generated by use of high-frequency microwaves, for example, microwaves with a frequency of 2.45 GHz. With high-density plasma, which has the characteristic of having a low electron temperature, a layer can be formed with less plasma damage and fewer defects compared to a layer formed by conventional plasma treatment because the kinetic energy of an active species is low. In addition, carrier mobility can be increased because roughness of the surface of the gate insulating film 52b can be reduced.

### Embodiment Mode 10

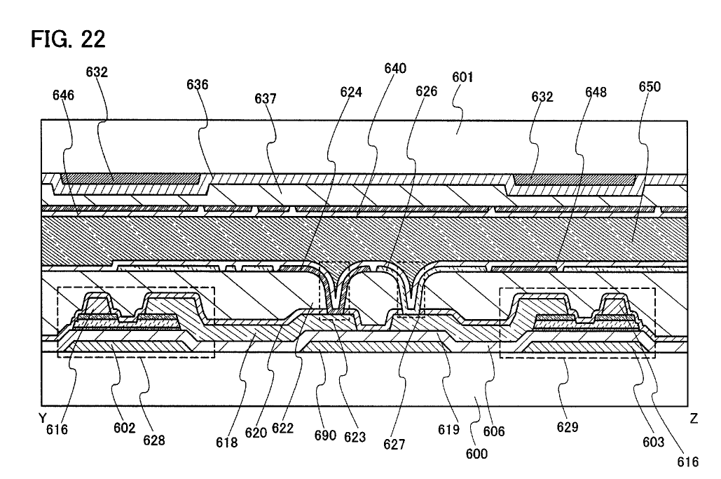

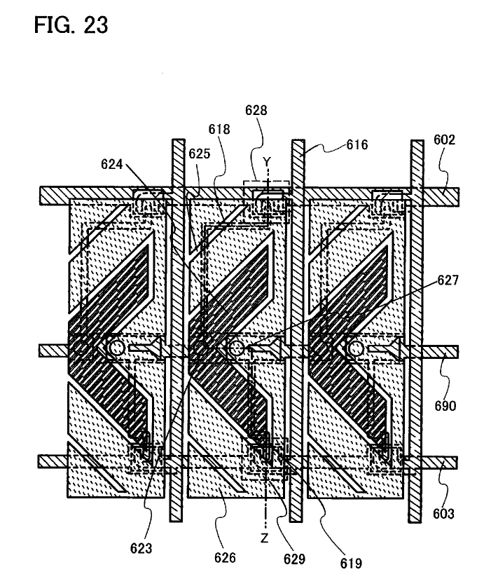

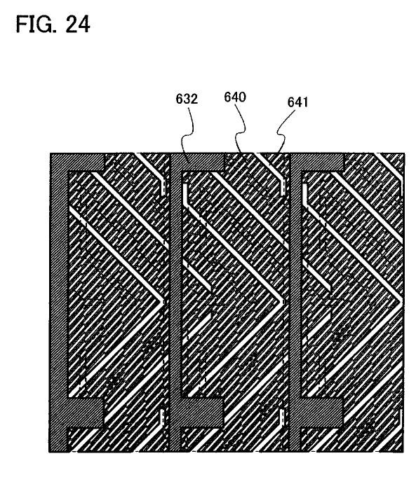

In this embodiment mode, a liquid crystal display device including the thin film transistor described in Embodiment Mode 1 will be described below as one mode of a display device. Here, a vertical alignment (VA) liquid crystal display device will be described with reference to FIG. 22, FIG. 23, and FIG. 24. The VA liquid crystal display device employs one mode for controlling alignment of liquid crystal molecules of a liquid crystal panel. The VA liquid crystal display device employs a mode in which liquid crystal molecules are vertical to a panel surface when voltage is not applied. In particular, in this embodiment mode, it is devised that a pixel is divided into several regions (sub-pixels) so that molecules are aligned in different directions in different regions. This is referred to as multi-domain or multi-domain design. In the following description, a liquid crystal display device with multi-domain design is described.

FIG. 22 and FIG. 23 illustrate a pixel structure of a VA liquid crystal panel. FIG. 23 is a plan view of a substrate 600. FIG. 22 illustrates a cross-sectional structure along a line Y-Z in FIG. 23. The following description will be made with reference to both the drawings.

In this pixel structure, a plurality of pixel electrodes is included in one pixel, and a thin film transistor is connected to each pixel electrode through a planarization film 622. Each thin film transistor is driven by a different gate signal. That is, a pixel of multi-domain design has a structure in which a signal applied to each pixel electrode is independently controlled.

A pixel electrode 624 is connected to a thin film transistor 628 through a wiring 618 in a contact hole 623. In a contact hole 627, a pixel electrode 626 is connected to a thin film transistor 629 through a wiring 619. A gate wiring 602 of the thin film transistor 628 and a gate wiring 603 of the thin film transistor 629 are separated so that different gate signals can be given thereto. In contrast, a wiring 616 functioning as a data line is used in common for the thin film transistors 628 and 629. The thin film transistors 628 and 629 can be manufactured by the method described in any of Embodiment Modes 4 to 8.

The pixel electrodes 624 and 626 have different shapes and are separated by a slit 625. The pixel electrode 626 surrounds the pixel electrode 624, which has a V-shape. Timings of voltage application are varied between the pixel electrode 624 and the pixel electrode 626 by the thin film transistor 628 and the thin film transistor 629, so that alignment of liquid crystals is controlled. When different gate signals are supplied to the gate wiring 602 and the gate wiring 603, operation timings of the thin film transistor 628 and the thin film transistor 629 can be varied. An alignment film 648 is formed over the pixel electrodes 624 and 626.

A counter substrate 601 is provided with a light-blocking film 632, a coloring film 636, and a counter electrode 640. In addition, a planarization film 637 is formed between the coloring film 636 and the counter electrode 640 so that alignment disorder of liquid crystals is prevented. Further, an alignment film 646 is formed on the counter electrode 640. FIG. 24 illustrates a structure of a counter substrate side. A slit 641 is formed in the counter electrode 640 which is used in common between different pixels. The slit 641 and the slit 625 on the side of the pixel electrodes 624 and 626 are alternately arranged in an engaging manner; thus, an oblique electric field is effectively generated, and the alignment of liquid crystals can be controlled. Accordingly, a direction of alignment of the liquid crystals can be made different depending on location and the viewing angle is widened.

In this specification, a substrate, a coloring film, a light-blocking film, and a planarization film form a color filter. Note that either the light-blocking film or the planarization film, or both of them are not necessarily formed over the substrate.

The coloring film has a function of preferentially transmitting light of a predetermined wavelength range, among light of the wavelength range of visible light. In general, a coloring film which preferentially transmits light of a wavelength range of red light, a coloring film which preferentially transmits light of a wavelength range of blue light, and a coloring film which preferentially transmits light of a wavelength range of green light are combined to be used for the color filter. However, the combination of the coloring films is not limited to the above combination.

The pixel electrode 624, a liquid crystal layer 650, and the counter electrode 640 overlap with each other to form a first liquid crystal element. Further, a second liquid crystal element is formed by overlapping of the pixel electrode 626, the liquid crystal layer 650, and the counter electrode 640. Furthermore, the multi-domain structure is employed in which the first liquid crystal element and the second liquid crystal element are provided for one pixel.

Although a vertical alignment (VA) liquid crystal display device is described here, the element substrate formed using the thin film transistor in accordance with Embodiment Mode 1 can also be applied to an FFS mode liquid crystal display device, an IPS mode liquid crystal display device, a TN mode liquid crystal display device, and the like.

The liquid crystal display device can be manufactured through the above-described process. Since an inverted staggered thin film transistor with small off-current and excellent electric characteristics is used for the liquid crystal display device of this embodiment mode, the liquid crystal display device can have high contrast and high visibility.

Note that any of Embodiment Modes 1 to 9 can be applied to this embodiment mode as appropriate.

### Embodiment Mode 11

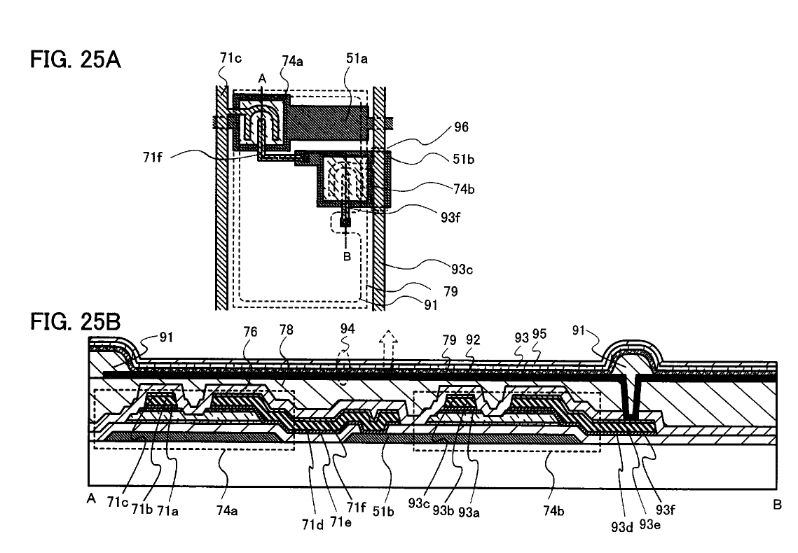

In this embodiment mode, a light-emitting display device including the thin film transistor described in Embodiment Mode 1 will be described as one mode of a display device, and a structure of a pixel included in the light-emitting display device will be described. FIG. 25A illustrates one mode of a top view of a pixel. FIG. 25B illustrates one mode of a cross-sectional structure of the pixel along a line A-B in FIG. 25A.

A light-emitting device includes a light-emitting element utilizing electroluminescence here. Light-emitting elements utilizing electroluminescence are classified according to whether a light-emitting material is an organic compound or an inorganic compound. In general, the former is referred to as an organic EL element, and the latter as an inorganic EL element. In addition, in this embodiment mode, the manufacturing process of the thin film transistor in accordance with the above embodiment mode can be used.

In the case of an organic EL element, by applying voltage to a light-emitting element, electrons and holes are injected from a pair of electrodes into a layer including an organic compound with a light-emitting property to cause a current flow. Then, by recombination of these carriers (electrons and holes), the organic compound with a light-emitting property forms an excited state, and light is emitted when the excited state returns to a ground state. Due to the above mechanism, such a light-emitting element is called a current excitation type light-emitting element.

Inorganic EL elements are classified according to their element structures, into a dispersion type inorganic EL element and a thin-film type inorganic EL element. The dispersion type inorganic EL element has a light-emitting layer in which particles of a light-emitting material are dispersed in a binder. The mechanism of light emission of the dispersion type inorganic EL element is donor acceptor recombination light emission, which utilizes a donor level and an acceptor level. The thin-film type inorganic EL element has a structure in which a light-emitting layer is interposed between dielectric layers and the light-emitting layer interposed between the dielectric layers is further interposed between electrodes, and adopts local emission in which inner shell electron transition of a metal ion is utilized as the mechanism of light emission. Note that the description is made here using an organic EL element as a light-emitting element. In addition, the description is made using channel-etched thin film transistors as a switching thin film transistor for controlling input of a signal to a pixel electrode and a thin film transistor for controlling driving of a light-emitting element, but a channel protective thin film transistor can also be used as appropriate.

In FIGS. 25A and 25B, a first thin film transistor 74a is a switching thin film transistor for controlling input of a signal to a pixel electrode, and a second thin film transistor 74b is a driving thin film transistor for controlling current or voltage supply to a light-emitting element 94.

A gate electrode of the first thin film transistor 74a is connected to a scanning line 51a, one of a source and a drain is connected to wirings 71a to 71c which function as a signal line, and wirings 71d to 71f connected to the other of the source and the drain is electrically connected to a gate electrode 51b of the second thin film transistor 74b. One of a source and a drain of the second thin film transistor 74b is connected to wirings 93a to 93c which function as a power source line, and the other of the source and the drain is electrically connected to a pixel electrode 79 of a display device. A gate electrode, a gate insulating film, and the wirings 93a to 93c which function as a power source line of the second thin film transistor 74b form a capacitor element 96, and the other of the source and the drain of the first thin film transistor 74a is connected to the capacitor element 96.

The capacitor element 96 corresponds to a capacitor element for holding a voltage between the gate and the source or between the gate and the drain (hereinafter referred to as a gate voltage) of the second thin film transistor 74b when the first thin film transistor 74a is turned off, and is not necessarily provided.

In this embodiment mode, the first thin film transistor 74a and the second thin film transistor 74b can be each formed in accordance with Embodiment Mode 4. In addition, although each of the first thin film transistor 74a and the second thin film transistor 74b is an n-channel thin film transistor, the first thin film transistor 74a and the second thin film transistor 74b may also be formed using an n-channel thin film transistor and a p-channel thin film transistor, respectively. Furthermore, both the first thin film transistor 74a and the second thin film transistor 74b may be formed using p-channel thin film transistors.

A protective insulating film 76 is formed over the first thin film transistor 74a and the second thin film transistor 74b, and a planarization film 78 is formed over the protective insulating film 76, and then the pixel electrode 79 functioning as a cathode is formed to be connected to the wirings 93d to 93f in a contact hole formed in the planarization film 78 and the protective insulating film 76. The planarization film 78 is preferably formed using an organic resin such as acrylic, polyimide, or polyamide, or a siloxane polymer. Since the pixel electrode 79 functioning as a cathode is uneven in the contact hole, a partition wall 91 having an opening is provided to cover the uneven portion of the pixel electrode 79. In the opening of the partition wall 91, a light-emitting layer 92 is formed so as to be in contact with the pixel electrode 79 functioning as a cathode, and a pixel electrode 93 functioning as an anode is formed so as to cover the light-emitting layer 92. A protective insulating film 95 is formed so as to cover the pixel electrode 93 functioning as an anode and the partition wall 91.

The light-emitting element 94 having a top emission structure is shown as a light-emitting element. Note that the light-emitting element 94 with a top emission structure can emit light even in the case where it is over the first thin film transistor 74a or the second thin film transistor 74b; thus, a light emission area can be increased. However, if the film located under the light-emitting layer 92 is uneven, the thickness is nonuniform due to unevenness, and the pixel electrode 93 functioning as an anode and the pixel electrode 79 functioning as a cathode are short-circuited, so that a display defect is caused. Therefore, it is preferable to provide the planarization film 78.

The light-emitting element 94 corresponds to a region where the pixel electrode 79 functioning as a cathode and the pixel electrode 93 functioning as an anode sandwich the light-emitting layer 92. In the case of the pixel illustrated in FIG. 25B, light from the light-emitting element 94 is emitted to the side of the pixel electrode 93 functioning as an anode as denoted by an outline arrow.

As the pixel electrode 79 functioning as a cathode, a known conductive film can be used as long as it has a low work function and reflects light. For example, Ca, Al, MgAg, AlLi, or the like is preferably used. The light-emitting layer 92 may be formed using a single layer or by stacking a plurality of layers. When the light-emitting layer 92 is formed using a plurality of layers, an electron-injecting layer, an electron-transporting layer, a light-emitting layer, a hole-transporting layer, and a hole-injecting layer are stacked in this order over the pixel electrode 79 functioning as a cathode. It is not necessary to form all of these layers. The pixel electrode 93 functioning as an anode is formed using a light-transmitting conductive material such as a film of indium oxide including tungsten oxide, indium zinc oxide including tungsten oxide, indium oxide including titanium oxide, indium tin oxide including titanium oxide, ITO, indium zinc oxide, or indium tin oxide to which silicon oxide is added.

A light-emitting element having a top emission structure in which light is extracted from a side opposite to a substrate is described here; however, a light-emitting element having a bottom emission structure in which light is extracted from the substrate side, or a light-emitting element having a dual emission structure in which light is extracted from both the substrate side and the side opposite to the substrate, can also be employed as appropriate.

Although an organic EL element is described here as a light-emitting element, an inorganic EL element can also be provided as a light-emitting element.

Note that, in this embodiment mode, an example in which the thin film transistor for controlling the driving of the light-emitting element (the driving thin film transistor) is electrically connected to the light-emitting element is described; however, a thin film transistor for controlling current may be connected between the driving thin film transistor and the light-emitting element.

Through the above-described process, a light-emitting display device can be manufactured. The light-emitting display device of this embodiment mode can have high contrast and high visibility because an inverted staggered thin film transistor with small off-current and excellent electric characteristics is used.

Note that any of Embodiment Modes 1 to 9 can be applied to this embodiment mode as appropriate.

### Embodiment Mode 12

In this embodiment mode, a structure of a display panel, which is one mode of a display device of the present invention, will be described.

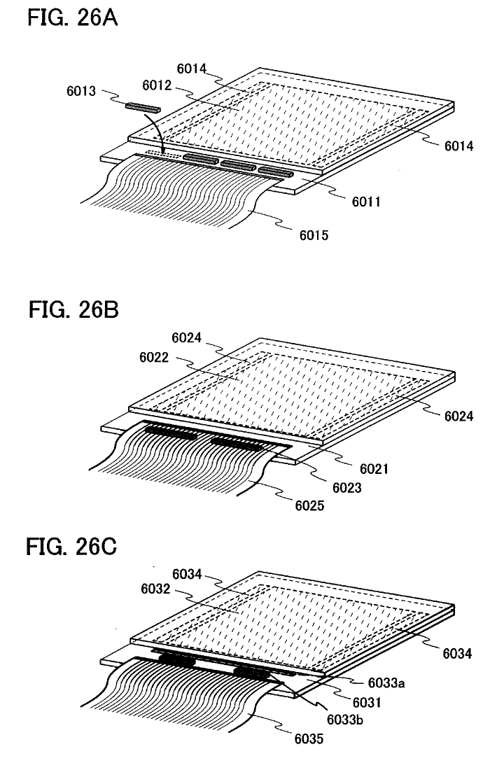

FIG. 26A illustrates a mode of a display panel in which a pixel portion 6012 formed over a substrate 6011 is connected to a signal line driver circuit 6013 that is formed separately. The pixel portion 6012 and a scanning line driver circuit 6014 are each formed using the thin film transistor in accordance with any of Embodiment Modes 1 to 3. By forming the signal line driver circuit using a transistor which has higher field-effect mobility, an operation of the signal line driver circuit which demands higher driving frequency than the scanning line driver circuit can be stabilized. Note that the signal line driver circuit 6013 may be formed using a transistor in which a single crystal semiconductor is used for a channel formation region, a thin film transistor in which a polycrystalline semiconductor is used for a channel formation region, or a transistor in which SOI is used for a channel formation region. The pixel portion 6012, the signal line driver circuit 6013, and the scanning line driver circuit 6014 are each supplied with potential of a power source, a variety of signals, and the like through an FPC 6015. Further, a protection circuit may be provided between the signal line driver circuit 6013 and the FPC 6015 or between the signal line driver circuit 6013 and the pixel portion 6012. The protection circuit includes one or more elements selected from the thin film transistor described in Embodiment Mode 4, a diode, a resistor element, a capacitor element, or the like. For example, a diode obtained by connecting the thin film transistor described in Embodiment Mode 1 or 2 as a diode can also be used.

Note that both the signal line driver circuit and the scanning line driver circuit may be formed over the same substrate as that of the pixel portion.

Also, when a driver circuit is separately formed, a substrate provided with the driver circuit is not always required to be attached to a substrate provided with a pixel portion, and may be attached to, for example, an FPC. FIG. 26B illustrates a mode of a display panel in which a signal line driver circuit 6023 is formed separately and is connected to a pixel portion 6022 and a scanning line driver circuit 6024 that are formed over a substrate 6021. The pixel portion 6022 and the scanning line driver circuit 6024 are each formed using a thin film transistor in which a microcrystalline germanium film is used for a channel formation region. The signal line driver circuit 6023 is connected to the pixel portion 6022 through an FPC 6025. The pixel portion 6022, the signal line driver circuit 6023, and the scanning line driver circuit 6024 are each supplied with potential of a power source, a variety of signals, and the like through the FPC 6025. Further, a protection circuit may be provided between the signal line driver circuit 6023 and the FPC 6025 or between the signal line driver circuit 6023 and the pixel portion 6022.

Furthermore, only a part of the signal line driver circuit or only a part of the scanning line driver circuit may be formed over the same substrate as that of the pixel portion with the use of a thin film transistor in which a microcrystalline germanium film is used for a channel formation region, and the rest may be formed separately and electrically connected to the pixel portion. FIG. 26C illustrates a mode of a display panel in which an analog switch 6033a included in the signal driver circuit is formed over a substrate 6031, over which a pixel portion 6032 and a scanning line driver circuit 6034 are formed, and a shift register 6033b included in the signal line driver circuit is formed separately over a different substrate and then attached to the substrate 6031. The pixel portion 6032 and the scanning line driver circuit 6034 are each formed using a thin film transistor in which a microcrystalline germanium film is used for a channel formation region. The shift register 6033b included in the signal line driver circuit is connected to the pixel portion 6032 through an FPC 6035. The pixel portion 6032, the signal line driver circuit, and the scanning line driver circuit 6034 are each supplied with a potential of a power source, a variety of signals, and the like through the FPC 6035. Further, a protection circuit may be provided between the signal line driver circuit and the FPC 6035 or between the signal line driver circuit and the pixel portion 6032.

As illustrated in FIGS. 26A to 26C, in the display device of this embodiment mode, the entire driver circuit or a part thereof can be formed over the same substrate as that of the pixel portion, using a thin film transistor in which a microcrystalline germanium film is used for a channel formation region.

Note that there is no particular limitation on a connection method of the substrate formed separately, and a known method such as a COG method, a wire bonding method, or a TAB method can be used. Further, a connection position is not limited to the position illustrated in FIGS. 26A to 26C, as long as electrical connection is possible. Alternatively, a controller, a CPU, a memory, and/or the like may be formed separately and connected.

Note that the signal line driver circuit used in the present invention includes a shift register and an analog switch. In addition to the shift register and the analog switch, another circuit such as a buffer, a level shifter, or a source follower may be included. Moreover, the shift register and the analog switch are not necessarily provided. For example, a different circuit such as a decoder circuit by which a signal line can be selected may be used instead of the shift register, or a latch or the like may be used instead of the analog switch.

### Embodiment Mode 13

The display device obtained by the present invention and the like can be used for an active matrix display panel. That is, the present invention can be applied to all electronic devices in which these display panels are incorporated into display portions.

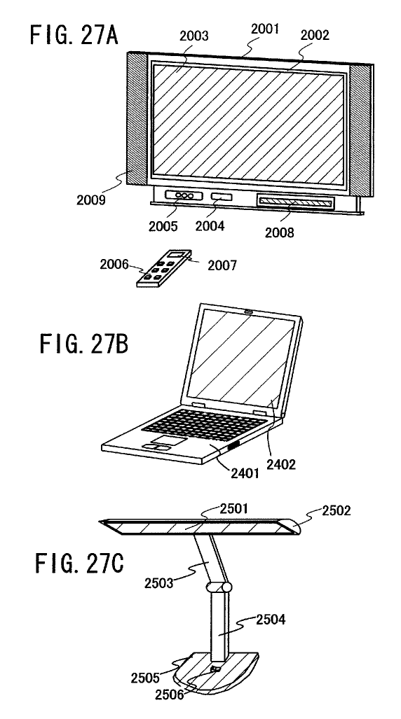

Examples of such electronic devices include cameras such as video cameras and digital cameras, head-mounted displays (goggle-type displays), car navigation systems, projectors, car stereo sets, personal computers, and portable information terminals (e.g., mobile computers, mobile phones, and e-book readers). Examples of these devices are illustrated in FIGS. 27A to 27C.

FIG. 27A illustrates a television device. A television device can be completed by incorporation of a display panel into a housing as illustrated in FIG. 27A. A main screen 2003 is formed using the display panel, and a speaker portion 2009, operation switches, and the like are provided as other additional accessories. In such a manner, a television device can be completed.

As illustrated in FIG. 27A, a display panel 2002 using display elements is incorporated into a housing 2001, and in addition to reception of general television broadcast by a receiver 2005, communication of information in one direction (from a transmitter to a receiver) or in two directions (between a transmitter and a receiver or between receivers) can be performed by connection to a wired or wireless communication network via a modem 2004. Operation of the television device can be carried out using switches that are incorporated into the housing or by a remote control device 2006 provided separately. A display portion 2007 that displays information output may be provided for the remote control device 2006.

Further, the television device may include a sub-screen 2008 formed using a second display panel for displaying channels, volume, and the like, in addition to the main screen 2003. In this structure, the main screen 2003 may be formed with a liquid crystal display panel, and the sub-screen 2008 may be formed with a light-emitting display panel. In addition, the main screen 2003 and the sub-screen 2008 may be each formed with a light-emitting display panel and the sub-screen 2008 may be set to be turned on and off.

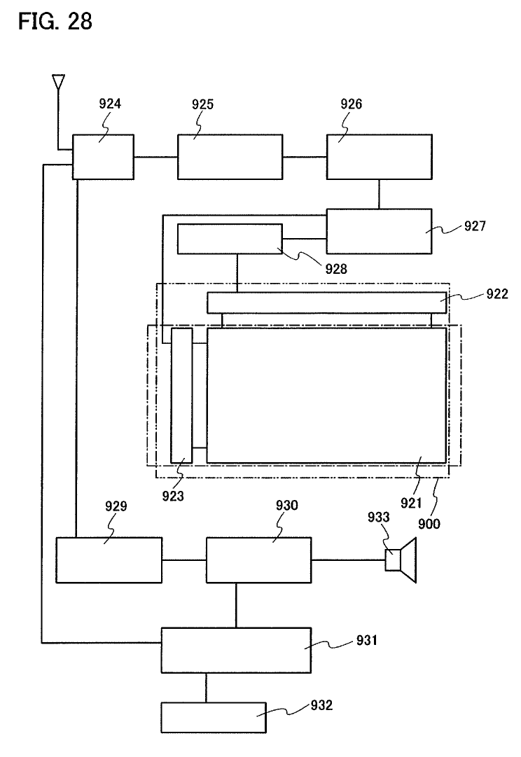

FIG. 28 is a block diagram illustrating the main structure of a television device. A display panel 900 is provided with a pixel portion 921. A signal line driver circuit 922 and a scanning line driver circuit 923 may be mounted on the display panel 900 by a COG method.

As structures of other external circuits, a video signal amplifier circuit 925 amplifying a video signal among signals received by a tuner 924, a video signal processing circuit 926 converting signals output from the video signal amplifier circuit 925 into chrominance signals corresponding to red, green, and blue, a control circuit 927 for converting the video signal into a signal which meets input specifications of a driver IC, and the like are provided on an input side of the video signal. The control circuit 927 outputs signals to the scanning line side and the signal line side. When digital driving is performed, a structure may be adopted in which a signal dividing circuit 928 is provided on the signal line side and an input digital signal is divided into m signals to be supplied.

An audio signal among signals received by the tuner 924 is sent to an audio signal amplifier circuit 929, and output from the audio signal amplifier circuit 929 is supplied to a speaker 933 through an audio signal processing circuit 930. A control circuit 931 receives control information on receiving station (receiving frequency) and volume from an input portion 932 and transmits a signal to the tuner 924 and the audio signal processing circuit 930.

It is needless to say that the present invention is not limited to a television device and can be applied to a variety of uses, such as a monitor of a personal computer, a large display medium such as an information display board at the train station, the airport, or the like, or an advertisement display board on the street.

The display device described in the above embodiment mode is applied to the main screen 2003 and the sub-screen 2008, so that mass productivity of the television device can be increased.

A portable computer illustrated in FIG. 27B includes a main body 2401, a display portion 2402, and the like. The display device described in the above embodiment mode is applied to the display portion 2402, so that mass productivity of the computer can be increased.

FIG. 27C illustrates a desk lamp (lighting equipment) including a lighting portion 2501, a shade 2502, an adjustable arm 2503, a support 2504, a base 2505, and a power source switch 2506. The desk lamp is manufactured using the light-emitting device described in the above embodiment mode for the lighting portion 2501. Note that the lighting equipment includes a ceiling light, a wall light, and the like. Use of the display device described in the above embodiment mode can increase mass productivity and provide inexpensive desk lamps.

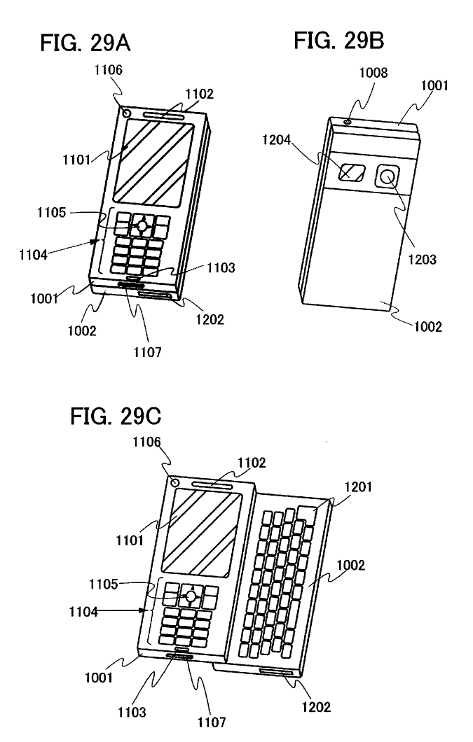

FIGS. 29A to 29C illustrate an example of a smartphone to which the present invention is applied. FIG. 29A is a front view, FIG. 29B is a rear view, and FIG. 29C is a front view in the case where two housings slide out. The smartphone 1000 has two housings 1001 and 1002. The smartphone 1000 has both a function of a mobile phone and a function of a portable information terminal, and incorporates a computer that is provided to conduct a variety of data processing in addition to verbal communication (voice calls); therefore, it is called a smartphone.

The housing 1001 includes a display portion 1101, a speaker 1102, a microphone 1103, operation keys 1104, a pointing device 1105, a front camera lens 1106, a jack 1107 for an external connection terminal, an earphone terminal 1108, and the like, while the housing 1002 includes a keyboard 1201, an external memory slot 1202, a rear camera 1203, a light 1204, and the like. In addition, an antenna is incorporated in the housing 1001.

Further, in addition to the above structure, the smartphone may incorporate a non-contact IC chip, a small size memory device, or the like.

The housing 1001 and the housing 1002 which are put together to be lapped with each other (FIG. 29A) slide out as illustrated in FIG. 29C. In the display portion 1101, the display device described in the above embodiment mode can be incorporated, and a display direction can be changed depending on a use mode. Because the front camera lens 1106 and the display portion 1101 are provided in the same plane, the smartphone can be used as a videophone. A still image and a moving image can be taken by the rear camera 1203 and the light 1204 by using the display portion 1101 as a viewfinder.

The speaker 1102 and the microphone 1103 can be used for videophone, recording, playback, and the like without being limited to verbal communication. With the use of the operation keys 1104, operation of incoming and outgoing of calls, simple information input such as electronic mail, scrolling of a screen, cursor motion, and the like are possible.

If much information is needed to be treated, such as documentation, use as a portable information terminal, and the like, the use of the keyboard 1201 is convenient. When the housing 1001 and the housing 1002 which are put together to be lapped with each other (FIG. 29A) slide out as illustrated in FIG. 29C and the smartphone is used as a portable information terminal, smooth operation can be conducted by using the keyboard 1201 and the pointing device 1105. To the jack 1107 for an external connection terminal, an AC adaptor and various types of cables such as a USB cable can be connected, and charging and data communication with a personal computer or the like are possible. Moreover, by inserting a storage medium into the external memory slot 1202, a large amount of data can be stored and moved.

In the rear surface of the housing 1002 (FIG. 29B), the rear camera 1203 and the light 1204 are provided, and a still image and a moving image can be taken by using the display portion 1101 as a viewfinder.

Further, the smartphone may have an infrared communication function, a USB port, a function of receiving one segment television broadcast, a non-contact IC chip, an earphone jack, or the like, in addition to the above-described functions and structures.

By employing the display device described in the above embodiment mode, mass productivity of the smartphone can be increased.

This application is based on Japanese Patent Application Serial No. 2007-312797 filed with Japan Patent Office on Dec. 3, 2007, the entire contents of which are hereby incorporated by reference.

What is claimed is:

1. A thin film transistor comprising:
a microcrystalline germanium film provided over a substrate;
a gate electrode provided adjacent to the microcrystalline germanium film with a gate insulating film therebetween; and
a buffer layer provided adjacent to a surface of the microcrystalline germanium film opposite to the gate electrode and the gate insulating film,
wherein the buffer layer comprises amorphous silicon.

2. A thin film transistor comprising:
a gate electrode formed over a substrate;
a gate insulating film formed over the gate electrode;
a microcrystalline germanium film formed over the gate insulating film;
a buffer layer comprising amorphous silicon formed over the microcrystalline germanium film; and
a pair of semiconductor films which are formed over the buffer layer and include an impurity element imparting one conductivity type.

3. A thin film transistor according to claim 2, wherein the microcrystalline germanium film includes an impurity element which serves as a donor.

4. A thin film transistor according to claim 2, wherein the gate insulating film has an uneven surface.

5. A thin film transistor according to claim 2, further comprising:
a pair of wirings which are in contact with the pair of semiconductor films including the impurity element imparting one conductivity type; and
a pixel electrode which is in contact with one of the pair of wirings.

6. A method for manufacturing a thin film transistor, comprising:
forming a microcrystalline germanium film over a gate insulating film by introducing a deposition gas including germanium, and hydrogen, and by applying high-frequency electric power;
forming a buffer layer over the microcrystalline germanium film by introducing a deposition gas including silicon, and hydrogen, and by applying high-frequency electric power; and
manufacturing a thin film transistor by using the gate insulating film, the microcrystalline germanium film, and the buffer layer.

7. A method for manufacturing a thin film transistor, comprising:
forming a gate insulating film over a gate electrode;
forming a germanium film over the gate insulating film;
etching a part of the germanium film by introducing at least one of fluorine, a fluoride gas, and hydrogen, and by applying high-frequency electric power;
forming a microcrystalline germanium film over the gate insulating film by introducing a deposition gas including germanium, and hydrogen, and by applying high-frequency electric power; and
forming a buffer layer over the microcrystalline germanium film by introducing a deposition gas including silicon, and hydrogen, and by applying high-frequency electric power,
wherein a thin film transistor is manufactured by using the gate electrode, the gate insulating film, the microcrystalline germanium film, and the buffer layer.

8. A method for manufacturing a thin film transistor according to claim 7, further comprising a step of exposing the gate insulating film to plasma by introducing at least one of fluorine, a fluoride gas, and hydrogen, and by applying high-frequency electric power before the formation of the germanium film.

9. A method for manufacturing a thin film transistor according to claim 7, wherein the formation of the germanium film is conducted by introducing a deposition gas including at least germanium, and applying high-frequency electric power.

10. A method for manufacturing a thin film transistor according to claim 7, wherein the germanium film is an amorphous germanium film or a microcrystalline germanium film.

11. A method for manufacturing a thin film transistor according to claim 7, wherein the germanium film comprises amorphous germanium formed by sputtering a germanium target with hydrogen or a rare gas.

12. A method for manufacturing a thin film transistor according to claim 7, wherein the formation of the gate insulating film is conducted by flowing a gas including an impurity element which serves as a donor into a reaction chamber.

13. A method for manufacturing a thin film transistor according to claim 7, wherein an impurity element which serves as a donor is added to the germanium film by introducing a gas including the impurity element which serves as the donor and applying high-frequency electric power.

14. A method for manufacturing a thin film transistor according to claim 7, wherein an impurity element which serves as a donor is added to the germanium film with the part of the germanium film etched by introducing a gas including the impurity element which serves as the donor in addition to at least one of the fluorine, the fluoride gas, and the hydrogen, and applying the high-frequency electric power.

15. A method for manufacturing a thin film transistor according to claim 7, wherein an impurity element which serves as a donor is added to the microcrystalline germanium film with the microcrystalline germanium film formed by introducing a gas including the impurity element which serves as the donor in addition to the deposition gas including germanium, and the hydrogen, and applying the high-frequency electric power.

16. A method for manufacturing a display device, comprising:
forming a gate insulating film over a gate electrode;
forming a germanium film over the gate insulating film;
etching a part of the germanium film by introducing at least one of fluorine, a fluoride gas, and hydrogen, and by applying high-frequency electric power;
forming a microcrystalline germanium film over the gate insulating film by introducing a deposition gas including germanium, and hydrogen, and by applying high-frequency electric power;
forming a buffer layer over the microcrystalline germanium film by introducing a deposition gas including silicon, and hydrogen, and by applying high-frequency electric power;
forming a pair of semiconductor films including an impurity element imparting one conductivity type over the buffer layer;
forming a pair of wirings over the pair of semiconductor films; and
forming a pixel electrode in contact with one of the pair of wirings.
